(19) United States
(12) Patent Application Publication
(10) Pub. No.: US 2025/0271764 A1
(43) Pub. Date: Aug. 28, 2025

(54) PHOTOSENSITIVE COMPOSITION, TRANSFER FILM, LAMINATE PRODUCTION METHOD, LAMINATE, AND SEMICONDUCTOR PACKAGE

(71) Applicant: FUJIFILM Corporation, Tokyo (JP)

(72) Inventors: Kunihiko KODAMA, Minamiashigara-shi (JP); Keigo YAMAGUCHI, Minamiashigara-shi (JP)

(73) Assignee: FUJIFILM Corporation, Tokyo (JP)

(21) Appl. No.: 19/064,845

(22) Filed: Feb. 27, 2025

Related U.S. Application Data
(63) Continuation of application No. PCT/JP2023/029782, filed on Aug. 18, 2023.

(30) Foreign Application Priority Data
Aug. 31, 2022 (JP) 2022-138352

(51) Int. Cl. G03F 7/075; G03F 7/004; G03F 7/028; G03F 7/11; G03F 7/32

(52) U.S. Cl. CPC G03F 7/0757; G03F 7/0045; G03F 7/028; G03F 7/0755; G03F 7/11; G03F 7/322

(57) ABSTRACT

The first object of the invention is to provide a photosensitive composition that makes it possible to form a pattern having excellent resolution and a low relative permittivity. The second object is to provide a transfer film, a laminate production method, a laminate, and a semiconductor package that are related to the photosensitive composition. The photosensitive composition includes: a siloxane polymer having a carboxy group; and a compound β having a structure that allows an amount of the carboxy group included in the siloxane polymer to reduce upon exposure.

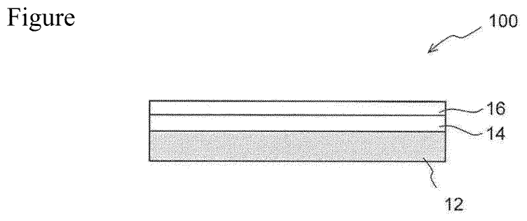

### CROSS-REFERENCE TO RELATED APPLICATIONS

This application is a Continuation of PCT International Application No. PCT/JP2023/029782 filed on Aug. 18, 2023, which claims priority under 35 U.S.C. § 119 (a) to Japanese Patent Application No. 2022-138352 filed on Aug. 31, 2022. The above applications are hereby expressly incorporated by reference, in their entirety, into the present application.

### TECHNICAL FIELD

The present invention relates to a photosensitive composition, a transfer film, a laminate production method, a laminate, and a semiconductor package.

### BACKGROUND ART

Photosensitive materials have been used in an interlayer insulating film inside a semiconductor chip, a connection layer (e.g., a buildup layer and an interposer) with respect to a printed circuit board, and the like. Further, in particular, as semiconductor wiring is becoming finer in these days, there is a demand for materials that enable the formation of an insulating film with high resolution.

For instance, Patent Literature 1 discloses a photosensitive siloxane resin composition as a photosensitive composition that enables the provision of a cured film applicable to an insulating film.

### CITATION LIST

### Patent Literature

[PATENT LITERATURE 1] WO2018/168435

### SUMMARY OF INVENTION

### Technical Problems

The present inventors have formed a pattern using the photosensitive composition described in WO2018/168435 and studied the pattern; as a result the present inventors found that there is room for further improvement in the resolution and further reduction in the relative permittivity.

Accordingly, an object of the present invention is to provide a photosensitive composition that makes it possible to form a pattern having excellent resolution and a low relative permittivity.

Another object of the present invention is to provide a transfer film, a laminate production method, a laminate, and a semiconductor package that are related to the photosensitive composition.

### Solution to Problems

The present inventors have made an intensive study to achieve the objects and as a result found that the foregoing objects can be achieved with the configuration below. The invention has been thus completed.
[1] A photosensitive composition comprising:
   a siloxane polymer having a carboxy group; and
   a compound β having a structure that allows an amount of the carboxy group included in the siloxane polymer to reduce upon exposure.
[2] The photosensitive composition according to [1],
   wherein the siloxane polymer has a repeating unit represented by Formula (a1) described below.
[3] The photosensitive composition according to [1] or [2],
   wherein the siloxane polymer further has a polymerizable group.
[4] The photosensitive composition according to any one of [1] to [3],
   wherein the compound β is a compound β having a structure capable of accepting an electron from the carboxy group included in the siloxane polymer in a photoexcited state.
[5] The photosensitive composition according to any one of [1] to [4],
   wherein the compound β is a nitrogen-containing aromatic compound.
[6] The photosensitive composition according to any one of [1] to [5], further comprising a filler.
[7] The photosensitive composition according to [6],
   wherein a content of the filler is 50 mass % or more with respect to a total solid content of the photosensitive composition.
[8] The photosensitive composition according to [6] or [7],
   wherein an average particle size of the filler is 300 nm or less.
[9] A photosensitive composition comprising:
   a siloxane polymer having a carboxy group and a polymerizable group;
   a compound β having a structure that allows an amount of the carboxy group included in the siloxane polymer to reduce upon exposure; and
   a filler,
   wherein the siloxane polymer has a repeating unit represented by Formula (a1) described below,
   the compound β is a nitrogen-containing aromatic compound, and
   an average particle size of the filler is 300 nm or less.
[10] The photosensitive composition according to any one of [1] to [9], further comprising a polymerizable compound.
[11] The photosensitive composition according to any one of [1] to [10], further comprising a photopolymerization initiator.
[12] A transfer film comprising:
   a temporary support; and
   a photosensitive layer formed of the photosensitive composition according to any one of [1] to.
[13] A laminate production method comprising:
   a step X1 of forming a photosensitive layer on a substrate by using the photosensitive composition according to any one of [1] to [11];
   a step X2 of subjecting the photosensitive layer to pattern exposure; and
   a step X3 of forming a pattern by developing the photosensitive layer exposed, with a developer.
[14] The laminate production method according to [13],
   wherein the step X2 is a step of reducing the amount of the carboxy group included in the siloxane polymer to change solubility with respect to a developer.
[15] The laminate production method according to or [14],
   wherein the substrate is an organic substrate having a copper pattern.
[16] The laminate production method according to any one of to [15],
wherein the developer is an alkaline developer.
[17] A laminate produced by the laminate production method according to any one of [13] to [16].
[18] A semiconductor package comprising the laminate according to [17].
[19] The photosensitive composition according to [9], comprising:
   a siloxane polymer having a carboxy group and a polymerizable group;
   a compound β having a structure that allows an amount of the carboxy group included in the siloxane polymer to reduce upon exposure; and
   a filler,
   wherein the siloxane polymer has a repeating unit represented by Formula (a1) described below,
   the compound β is a nitrogen-containing aromatic compound,
   an average particle size of the filler is 300 nm or less, and
   a content of the filler is 50 mass % or more with respect to a total solid content of the photosensitive composition.
[20] The photosensitive composition according to any one of [1] to [11], comprising:
   a siloxane polymer having a carboxy group; and
   a compound β having a structure that allows decarboxylation reaction of the carboxy group included in the siloxane polymer to occur upon exposure to thereby reduce an amount of the carboxy group included in the siloxane polymer,
   wherein the siloxane polymer has a repeating unit represented by Formula (a1) described below,
   the compound β includes acridine, 9-alkylacridine, quinoline that may have a substituent, or isoquinoline that may have a substituent,
   and in the repeating unit represented by Formula (a1), X represents an (n+1) valent linking group that is one or a combination of two or more selected from the group consisting of a linear or branched divalent aliphatic hydrocarbon group that may have a substituent, —O—, —S—, —SO₂—, >N—, —NR^{S1}—, and —CO—, and R^{S1} represents a hydrogen atom or a monovalent organic group.
[21] The photosensitive composition according to any one of [1] to [11], comprising:
   a siloxane polymer having a carboxy group; and
   a compound β having a structure that allows an amount of the carboxy group included in the siloxane polymer to reduce upon exposure,
   wherein the siloxane polymer having a carboxy group does not have a structure in which a hydrogen atom of the carboxy group is substituted with an acid labile group, and
   the photosensitive composition is substantially free of a polymerizable compound.
[22] The photosensitive composition according to any one of [1] to [11], comprising:
   a siloxane polymer having a carboxy group; and
   a compound β having a structure that allows an amount of the carboxy group included in the siloxane polymer to reduce upon exposure,
   wherein the photosensitive composition is substantially free of an acid generator, and
   the photosensitive composition is substantially free of a polymerizable compound.
[23] A cured film obtained by curing the photosensitive composition according to any one of [1] to [11] and [19] to [22].

### Advantageous Effects of Invention

The present invention can provide a photosensitive composition that makes it possible to form a pattern having excellent resolution and a low relative permittivity.

The present invention also can provide a transfer film, a laminate production method, a laminate, and a semiconductor package that are related to the photosensitive composition.

### BRIEF DESCRIPTION OF DRAWINGS

The FIGURE is a schematic view showing one example of a layer structure of a transfer film.

### DESCRIPTION OF EMBODIMENTS

The present invention is described in detail below.

In the present specification, a numerical range expressed using “to” means a range that includes numerical values stated before and after “to” as the range's lower and upper limit values, respectively.

In numerical ranges that are described stepwise in the present specification, an upper limit value or a lower limit value described in a certain numerical range may be replaced with an upper limit value or a lower limit value of another numerical range described stepwise. In addition, in a numerical range stated in the present specification, an upper limit value or a lower limit value of a certain numerical range may be replaced with a value described in Examples.

The term “step” in the present specification includes not only an independent step but also a step that is not clearly distinguishable from another step as long as an intended object of the step is achieved.

In the present specification, a temperature condition may be 25° C. unless otherwise specified. For instance, each step may be performed at a temperature of 25° C. unless otherwise specified.

In the present specification, “transparent” means that an average transmittance of visible light in the wavelength range of 400 to 700 nm is 80% or more, and preferably 90% or more.

The average transmittance of visible light is a value measured with a spectrophotometer, and for example, can be measured with a spectrophotometer U-3310 manufactured by Hitachi, Ltd.

In the present specification, “actinic ray” and “radiation” each mean a bright line spectrum of a mercury lamp such as g-rays, h-rays, and i-rays, far ultraviolet rays typified by an excimer laser, extreme ultraviolet rays (EUV light), X-rays, and electron beams (EB). In the present invention, light means an actinic ray or radiation.

Unless otherwise specified, “exposure” in the present specification encompasses not only exposure to light by a mercury lamp, far ultraviolet rays typified by an excimer laser, extreme ultraviolet rays, X-rays, EUV light, or the like, but also drawing by corpuscular beams such as electron beams and ion beams.

In the present specification, a content ratio of a repeating unit of a resin is a molar ratio unless otherwise specified.

In the present specification, a refractive index is a value measured with an ellipsometer at a wavelength of 550 nm unless otherwise specified.

In the present specification, unless otherwise specified, a molecular weight when there is a molecular weight distribution is a weight-average molecular weight (Mw). In the present specification, the weight-average molecular weight (Mw) and the number-average molecular weight (Mn) are values obtained by performing polystyrene conversion of values measured by gel permeation chromatography (GPC).

In the present specification, “(meth)acryloyl group” is a concept including both an acryloyl group and a methacryloyl group, and “(meth)acrylate” is a concept including both an acrylate and a methacrylate.

In the present specification, “water-soluble” means that the solubility in 100 g of water with a pH of 7.0 at a liquid temperature of 22° C. is 0.1 g or more.

“Solid content” of a composition means the content of constituent components forming a composition layer formed of the composition, and when the composition contains a solvent (for example, organic solvent, water, or the like), the solid content means the content of all components excluding the solvent. Even a liquid component is considered to be a solid as long as it is a constituent component of the composition layer.

In the present specification, unless otherwise specified, a thickness of a layer (film thickness) is an average thickness measured using a scanning electron microscope (SEM) for a thickness of 0.5 μm or more, and is an average thickness measured using a transmission electron microscope (TEM) for a thickness of less than 0.5 μm. The above-described average thickness is an average thickness obtained by forming a section to be measured using an ultramicrotome, measuring thicknesses of any five points, and arithmetically averaging the measurements.

### [Photosensitive Composition]

The photosensitive composition according to the embodiment of the present invention contains
a siloxane polymer having a carboxy group (hereinafter also called “specific siloxane polymer”); and
a compound β having a structure that allows the amount of the carboxy group included in the siloxane polymer to reduce upon exposure (hereinafter also simply called “compound β”).

While detailed mechanism of the action of the photosensitive composition according to the embodiment of the present invention is not clear, the present inventors presume as follows. In a photosensitive layer formed using the photosensitive composition, the polarity changes due to a reduction in the carboxy group content of the specific siloxane polymer in an exposed portion, and thus the solubility with respect to a developer changes. In other words, in the exposed portion, the solubility with respect to an alkaline developer decreases, and the solubility with respect to an organic solvent developer increases. On the other hand, in an unexposed portion, the solubility with respect to the developer does not substantially change. Hence, the photosensitive layer has a lithographic property, and a pattern having excellent resolution can be formed.

In addition, the carboxy group content of the specific siloxane polymer is reduced in the formed pattern, and this leads to a low relative permittivity.

One mechanism of reduction in the carboxy group content of the specific siloxane polymer upon exposure is, for instance, a mechanism associated with decarboxylation. The reduction in the carboxy group content of the specific siloxane polymer due to decarboxylation means that a carboxy group is eliminated as carbon dioxide (CO₂), and the phrase does not include the change of a carboxy group to a group other than a carboxy group by esterification or the like. It is presumed that when the photosensitive layer formed using the photosensitive composition is exposed, decarboxylation reaction of a carboxy group included in the specific siloxane polymer may occur by action of the compound β.

One example of the embodiment of the photosensitive composition is shown below.

### Embodiment X-1

A photosensitive composition containing the specific siloxane polymer, the compound β, and a filler, and being substantially free of a polymerizable compound and a photopolymerization initiator.

### Embodiment X-2

A photosensitive composition containing the specific siloxane polymer, the compound β, a filler, and a polymerizable compound, and being substantially free of a photopolymerization initiator.

### Embodiment X-3

A photosensitive composition containing the specific siloxane polymer, the compound β, and a filler, as well as a polymerizable compound and a photopolymerization initiator.

In Embodiment X-1, for “substantially free of a polymerizable compound,” it suffices if the polymerizable compound content is less than 1 mass %, preferably 0.5 mass % or less, and more preferably 0.1 mass % or less with respect to the total solid content of the photosensitive composition.

In Embodiments X-1 and X-2, for “substantially free of a photopolymerization initiator,” it suffices if the photopolymerization initiator content is less than 0.1 mass %, preferably 0 to 0.05 mass %, and more preferably 0 to 0.01 mass % with respect to the total solid content of the photosensitive composition.

As an embodiment of the photosensitive composition, Embodiment X-1 or X-3 is preferred, and Embodiment X-3 is more preferred.

A pattern formed from the photosensitive composition having more excellent resolution and/or a low relative permittivity is sometimes referred to as “the effect of the present invention is more excellent.”

Components that may be contained in the photosensitive composition according to the embodiment of the present invention are described in detail below.

### [Specific Siloxane Polymer]

The photosensitive composition contains a siloxane polymer having a carboxy group (specific siloxane polymer).

The specific siloxane polymer is a polymer having a carboxy group and a siloxane bond.

The specific siloxane polymer preferably contains a repeating unit having a carboxy group because the effect of the present invention is more excellent.

The repeating unit having a carboxy group is preferably a repeating unit having a carboxy group as well as a siloxane bond, more preferably a repeating unit represented by Formula (a0) below, even more preferably a repeating unit of M body having a carboxy group or a repeating unit of T body having a carboxy group, particularly preferably a repeating unit of T body having a carboxy group, and most preferably a repeating unit represented by Formula (a1).

As the repeating unit represented by Formula (a1), in particular, a repeating unit represented by Formula (a1a) or Formula (a1b) is preferred because the effect of the present invention is more excellent.

The repeating unit of M body refers to a repeating unit in which, of the four bonds of a silicon atom, two bonds are each bonded to an oxygen atom, and the other two bonds are each bonded to a hydrogen atom or a monovalent organic group.

The repeating unit of T body refers to a repeating unit in which, of the four bonds of a silicon atom, three bonds are each bonded to an oxygen atom, and the remaining one bond is bonded to a hydrogen atom or a monovalent organic group.

Repeating units represented by Formula (a0), Formula (a1), Formula (a1a), and Formula (a1b) are described below.

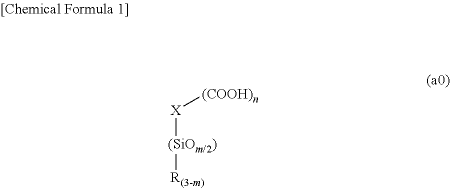

In the formula, m represents an integer of 1 to 3. For m, 2 or 3 is preferred, and 3 is more preferred.

R represents a hydrogen atom or a monovalent organic group. The monovalent organic group represented by R is not particularly limited, and examples thereof include a group same as or similar to a monovalent organic group represented by R^{T1} that may be included in Formula (b2) and Formula (b3) which will be described later.

When m is 1, a plurality of R's may be the same or different. When m is 3, R is not present.

X represents an (n+1) valent linking group. X is as defined for X in Formula (a1) below, and its preferable embodiment is also the same.

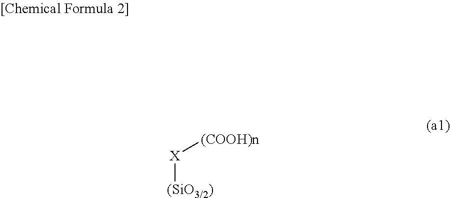

In Formula (a1), X represents an (n+1) valent linking group.

Examples of the (n+1) valent linking group include a group that is one or a combination of two or more selected from the group consisting of a divalent aliphatic hydrocarbon group, a divalent aromatic hydrocarbon group, —O—, —S—, —SO₂—, >N—, —NR^{S1}—, and —CO—. R^{S1} represents a hydrogen atom or a monovalent organic group (e.g., alkyl group).

The divalent aliphatic hydrocarbon group may be linear, branched, or cyclic.

The number of carbon atoms of a linear or branched divalent aliphatic hydrocarbon group is preferably 1 to 30, more preferably 1 to 20, and even more preferably 1 to 10. Examples of the divalent aliphatic hydrocarbon group include an alkylene group, an alkenylene group, and an alkynylene group, and of these, an alkylene group is preferred. The number of carbon atoms of a cyclic divalent aliphatic hydrocarbon group is preferably 6 to 20, more preferably 6 to 10, and even more preferably 6. The cyclic divalent aliphatic hydrocarbon group may be a cycloalkyl group or a cycloalkenyl group.

The number of carbon atoms of the divalent aromatic hydrocarbon group is preferably 6 to 20, more preferably 6 to 10, and even more preferably 6. Examples of the divalent aromatic hydrocarbon group include a phenylene group.

The divalent aliphatic hydrocarbon group and the divalent aromatic hydrocarbon group may further have a substituent.

In the divalent aliphatic hydrocarbon group, at least one of methylene groups (—CH₂—) constituting the aliphatic hydrocarbon group may be substituted with a group represented by Formula (A) below (* represents a bonding position). When the group represented by Formula (A) below is included in the divalent aliphatic hydrocarbon group, the group represented by Formula (A) below may also serve as a polymerizable group.

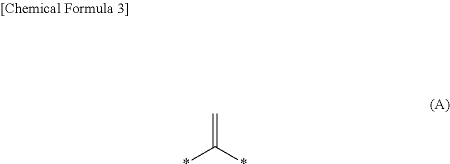 [SMILES: *C(*)=C]

The number of atoms, excluding hydrogen atoms, constituting the (n+1) valent linking group is preferably 5 to 300, more preferably 5 to 200, even more preferably 5 to 100, and particularly preferably 5 to 60.

The monovalent organic group represented by R^{S1} is preferably an alkyl group having 1 to 10 carbon atoms, more preferably an alkyl group having 1 to 6 carbon atoms, and even more preferably a methyl group or an ethyl group.

The (n+1) valent linking group represented by X is, in particular, preferably an (n+1) valent linking group containing an amide bond or an (n+1) valent linking group containing a sulfide bond, and more preferably an (n+1) valent linking group containing an amide bond.

The amide bond refers to a bond represented by —NR^{S2}—CO—. The sulfide bond refers to a bond represented by —S—. R^{S2} represents a hydrogen atom or a monovalent organic group.

In the (n+1) valent linking group containing an amide bond, it suffices if the number of amide bonds is 1 or more, and for example, the number is 1 to 3. In the (n+1) valent linking group containing a sulfide bond, it suffices if the number of sulfide bonds is 1 or more, and for example, the number is 1 to 3.

Examples of the (n+1) valent linking group containing an amide bond include a group that contains one or more amide bonds and that is one or a combination of two or more selected from the group consisting of a divalent aliphatic hydrocarbon group, a divalent aromatic hydrocarbon group, —O—, —S—, —SO₂—, >N—, —NR^{S1}—, and —CO—. R^{S1} represents a hydrogen atom or a monovalent organic group (e.g., alkyl group).

The divalent aliphatic hydrocarbon group, the divalent aromatic hydrocarbon group, and the monovalent organic group represented by R^{S1} described above are as defined earlier for those exemplified to describe the (n+1) valent linking group, and their preferable embodiments are also the same.

The number of atoms, excluding hydrogen atoms, constituting the (n+1) valent linking group containing an amide bond is preferably 5 to 300, more preferably 5 to 200, even more preferably 5 to 100, and particularly preferably 5 to 60.

Examples of the (n+1) valent linking group containing an amide bond include -L^{S1}-A^{S1}-L^{S2}- and a group represented by Formula (LS1) below.

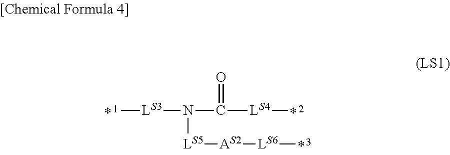

L^{S1} to L^{S6} each independently represent an alkylene group, a cycloalkylene group, an alkenylene group, a cycloalkenylene group, or an arylene group, and of these, an alkylene group, a cycloalkylene group, an alkenylene group, or a cycloalkenylene group is preferable.

The alkylene group and the alkenylene group represented by L^{S1} to L^{S6} may be linear or branched and are preferably linear. The number of carbon atoms of the alkylene group and the alkenylene group represented by L^{S1} to L^{S6} is preferably 1 to 12, more preferably 1 to 10, and even more preferably 1 to 6.

The number of carbon atoms of the cycloalkylene group and the cycloalkenylene group represented by L^{S1} to L^{S6} is preferably 6 to 20, more preferably 6 to 10, and even more preferably 6.

The number of carbon atoms of the arylene group represented by L^{S1} to L^{S6} is preferably 6 to 20, more preferably 6 to 10, and even more preferably 6.

The alkylene group, the cycloalkylene group, the alkenylene group, the cycloalkenylene group, or the arylene group represented by L^{S1} to L^{S6} may further have a substituent.

A^{S1} and A^{S2} each independently represent an amide bond (—NR^{S2}—CO—).

R^{S2} represents a hydrogen atom or a monovalent organic group and preferably a hydrogen atom.

The monovalent organic group represented by R^{S2} is not particularly limited and is preferably an alkyl group having 1 to 10 carbon atoms, more preferably an alkyl group having 1 to 6 carbon atoms, and even more preferably a methyl group or an ethyl group.

In Formula (LS1), *¹, *², and *³ each represent a bonding position.

One of *¹, *², and *³ in Formula (LS1) is a bonding position with a silicon atom clearly shown in Formula (a1), and the other two thereof are bonding positions with a carboxy group clearly shown in Formula (a1).

Examples of the (n+1) valent linking group containing a sulfide bond include a group that contains one or more sulfide bonds and that is one or a combination of two or more selected from the group consisting of a divalent aliphatic hydrocarbon group, a divalent aromatic hydrocarbon group, —O—, —SO₂—, >N—, —NR^{S1}—, and —CO—. R^{S1} represents a hydrogen atom or a monovalent organic group (e.g., alkyl group).

The divalent aliphatic hydrocarbon group, the divalent aromatic hydrocarbon group, and the monovalent organic group represented by R^{S1} described above are as defined earlier for those exemplified to describe the (n+1) valent linking group, and their preferable embodiments are also the same.

The number of atoms, excluding hydrogen atoms, constituting the (n+1) valent linking group containing a sulfide bond is preferably 5 to 300, more preferably 5 to 200, even more preferably 5 to 100, and particularly preferably 5 to 60.

Examples of the (n+1) valent linking group containing a sulfide bond include -L^{S7}-S-L^{S8}-.

LS7 and L^{S8} are as defined for L^{S1} to L^{S6} described above, and their preferable embodiments are also the same.

In particular, L^{S7} and L^{S8} are preferably a linear alkylene group or a linear alkenylene group.

In Formula (a1), n represents an integer of 1 or more.

n is preferably 1 to 5 and more preferably 1 or 2.

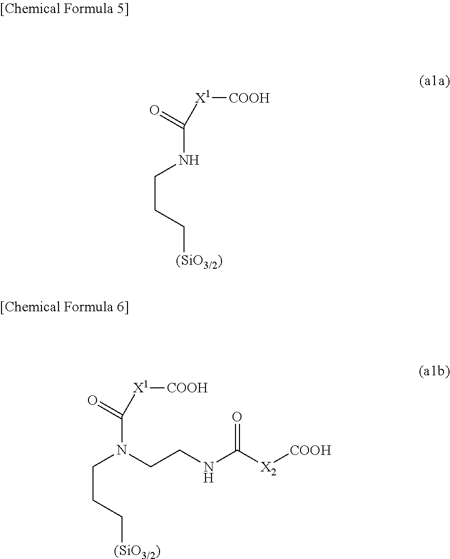

In Formula (a1a) and Formula (a1b), X¹ and X² are as defined for L^{S1} to L^{S6} described above, and their preferable embodiments are also the same.

The content of the repeating unit having a carboxy group (preferably the repeating unit represented by Formula (a1)) is preferably 10 to 100 mol %, more preferably 20 to 100 mol %, even more preferably 30 to 90 mol %, and particularly preferably 40 to 80 mol % with respect to all the repeating units of the siloxane polymer.

The specific siloxane polymer may include one type or two or more types of the repeating unit having a carboxy group (preferably the repeating unit represented by Formula (a1)). When two or more types are included, it is preferable that the total content thereof fall within the foregoing numerical range.

Specific examples of the repeating unit having a carboxy group (preferably the repeating unit represented by Formula (a1)) are shown below, but not limited thereto.

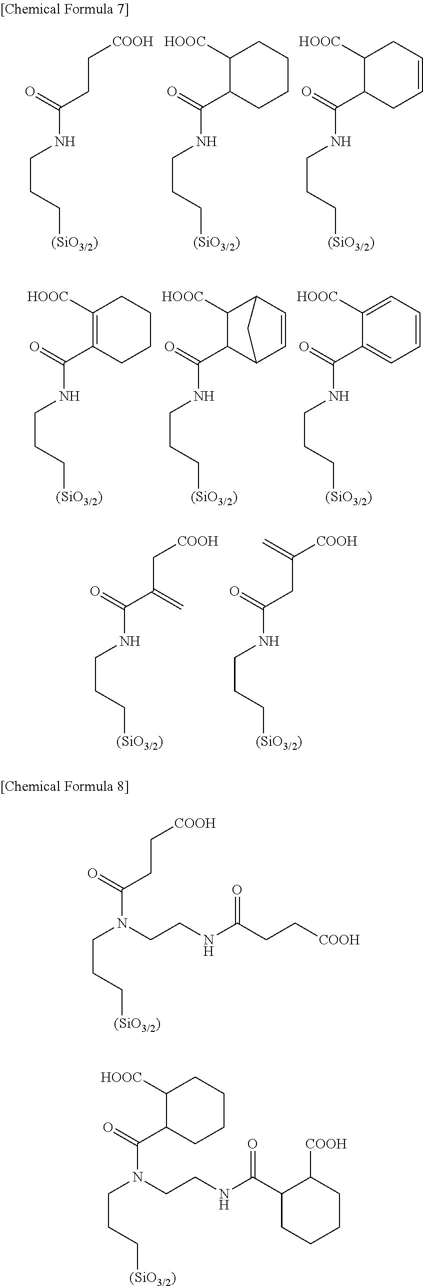

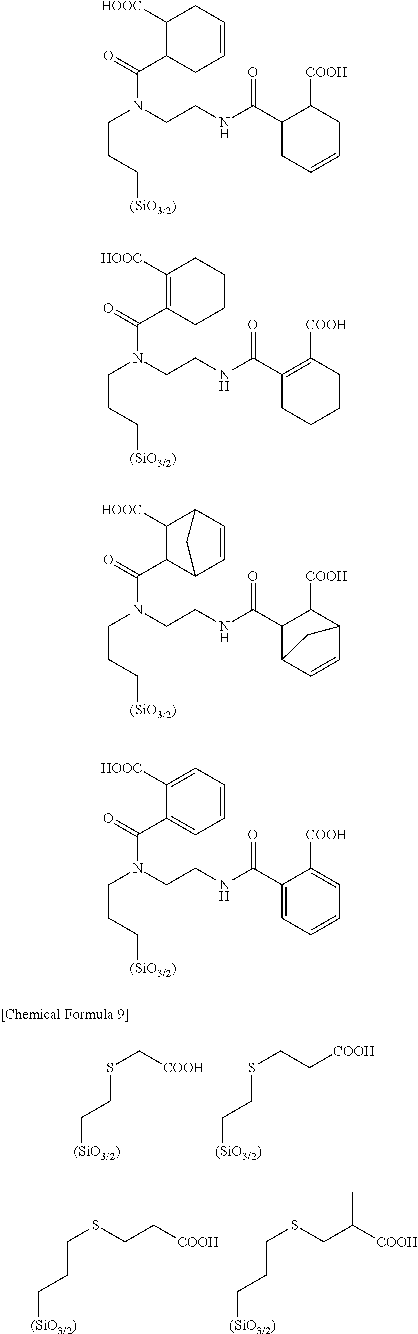

The specific siloxane polymer preferably has a polymerizable group.

Examples of the polymerizable group include a radically polymerizable group and a cationically polymerizable group.

The radically polymerizable group is preferably a (meth)acryloyl group or a vinyl group, more preferably a vinyl group, and even more preferably a vinyl group directly bonded to a silicon atom.

The cationically polymerizable group is preferably an epoxy group or an oxetane group.

The epoxy group as the cationically polymerizable group may be present as a part of a cyclic structure. That is, the epoxy group may form a polycyclic structure having an epoxy ring and another ring (e.g., cycloalkane ring). Examples of the cationically polymerizable group having an epoxy group as a part of a cyclic structure include a 1,2-epoxycyclohexyl group.

The oxetane group as the cationically polymerizable group may be present as a part of a cyclic structure. That is, the oxetane group may form a polycyclic structure having an oxetane ring and another ring (e.g., cycloalkane ring).

The introducing position of the polymerizable group is not particularly limited, and the polymerizable group may be introduced in the above-described repeating unit having a carboxy group or introduced in a position other than the above-described repeating unit having a carboxy group.

Preferably, the specific siloxane polymer further includes a repeating unit having a polymerizable group different from the above-described repeating unit having a carboxy group because the effect of the present invention is more excellent.

The repeating unit having a polymerizable group is preferably a repeating unit having a polymerizable group and containing a siloxane bond.

The repeating unit having a polymerizable group and containing a siloxane bond is preferably a repeating unit in which a group represented by —Y—(Z)p is bonded to a silicon atom of the siloxane bond. Y, Z, and p in the above formula are as defined for Y, Z, and p in Formulae (b1) to (b3) to be described below, and their preferable embodiments are also the same.

Examples of the repeating unit having a polymerizable group and containing a siloxane bond include a repeating unit of D body having a polymerizable group (e.g., a repeating unit represented by Formula (b3) below), a repeating unit of M body having a polymerizable group (e.g., a repeating unit represented by Formula (b2) below), and a repeating unit of T body having a polymerizable group (e.g., a repeating unit represented by Formula (b1) below).

It suffices if the number of polymerizable groups in the repeating unit having a polymerizable group is 1 or more, and for example, the number is preferably 1 to 3 and more preferably 1.

The repeating unit of D body refers to a repeating unit in which, of the four bonds of a silicon atom, one bond is bonded to an oxygen atom, and the other three bonds are each bonded to a hydrogen atom or a monovalent organic group.

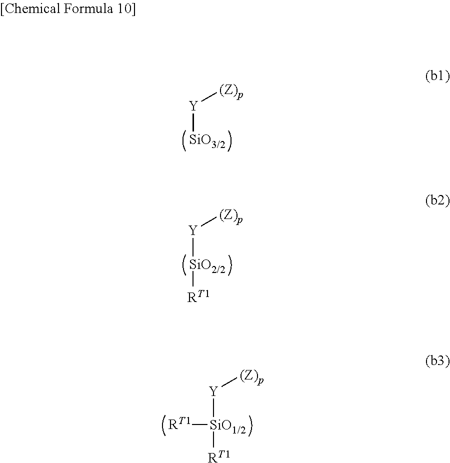

In Formula (b1), Formula (b2), and Formula (b3), Y represents a single bond or a (p+1) valent linking group. When Y represents a single bond, p represents 1.

Examples of the (p+1) valent linking group represented by Y include a group that is one or a combination of two or more selected from the group consisting of a divalent aliphatic hydrocarbon group, a divalent aromatic hydrocarbon group, —O—, —SO₂—, >N—, —NR^{T2}—, and —CO—. R^{T2} represents a hydrogen atom or a monovalent organic group (e.g., alkyl group).

The divalent aliphatic hydrocarbon group and the divalent aromatic hydrocarbon group are as defined for those the above-described (n+1) valent linking group may have, and their preferable embodiments are also the same.

The number of atoms, excluding hydrogen atoms, constituting the (p+1) valent linking group is preferably 5 to 300, more preferably 5 to 200, and even more preferably 5 to 100.

The monovalent organic group represented by R^{T2} is not particularly limited and is preferably an alkyl group having 1 to 10 carbon atoms, more preferably an alkyl group having 1 to 6 carbon atoms, and even more preferably a methyl group or an ethyl group.

Specific examples of the (p+1) valent linking group represented by Y include -L^{T3}-L^{T4}-.

L^{T3} represents an alkylene group having 1 to 20 carbon atoms (preferably 1 to 10 carbon atoms) in which a methylene group (—CH₂—) in the chain may be substituted with a linking group that is one or a combination of two or more selected from the group consisting of —O—, —NH—, and —CO—. An atom in L^{T3} at the bonding position with L^{T4} is preferably a carbon atom.

L^{T4} represents —O— or —NR^{T2}—. R^{T2} is as defined above.

Y is preferably a single bond because the effect of the present invention is more excellent.

In Formula (b1), Formula (b2), and Formula (b3), Z represents a polymerizable group.

Examples of the polymerizable group are the same as those of the polymerizable group described above.

In Formula (b1), Formula (b2), and Formula (b3), p represents an integer of 1 or more, preferably 1 to 5, more preferably 1 or 2, and even more preferably 1.

In Formula (b2) and Formula (b3), R^{T1} represents a hydrogen atom or a monovalent organic group.

The monovalent organic group represented by R^{T1} is not particularly limited and is preferably an alkyl group having 1 to 6 carbon atoms or a phenyl group. In particular, the number of carbon atoms of the alkyl group is preferably 1 to 3 and more preferably 1 or 2. The alkyl group and the phenyl group may have a substituent.

The content of the repeating unit having a polymerizable group is preferably 10 to 90 mol %, more preferably 20 to 80 mol %, and even more preferably 30 to 70 mol % with respect to all the repeating units of the specific siloxane polymer.

The specific siloxane polymer may include one type or two or more types of the repeating unit having a polymerizable group. When two or more types are included, it is preferable that the total content thereof fall within the foregoing numerical range.

Specific examples of the repeating unit having a polymerizable group are shown below, but not limited thereto.

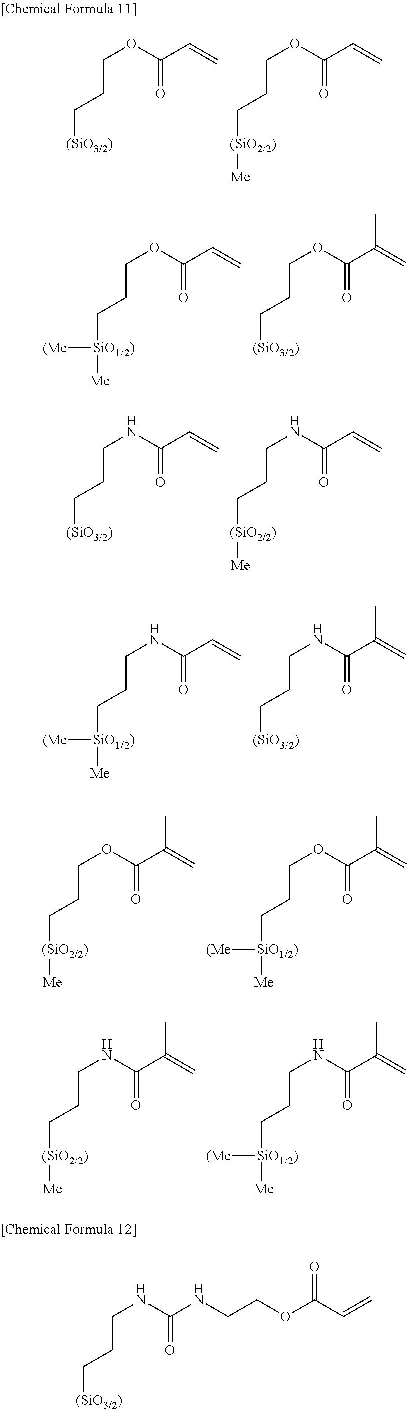

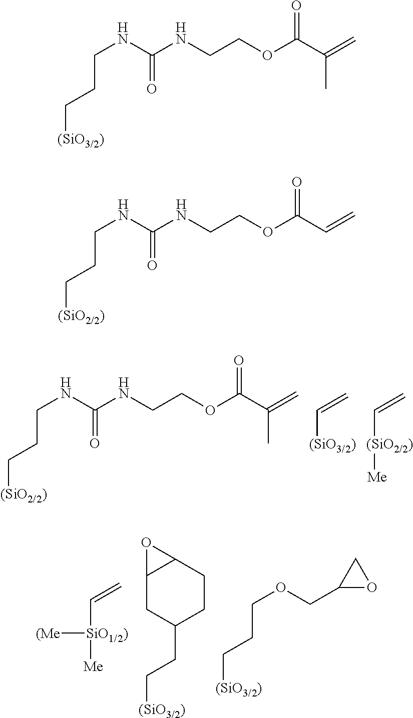

The specific siloxane polymer may further include another repeating unit (hereinafter also called “the other repeating unit”) different from the repeating unit having a carboxy group and the repeating unit having a polymerizable group which are described above.

The other repeating unit is preferably a repeating unit containing a siloxane bond.

The repeating unit containing a siloxane bond may be any of a repeating unit of D body, a repeating unit of M body, a repeating unit of T body, and a repeating unit of Q body.

The repeating unit of D body, the repeating unit of M body, and the repeating unit of T body are, for instance, a repeating unit represented by Formula (c3), a repeating unit represented by Formula (c2), and a repeating unit represented by Formula (c1), respectively.

The repeating unit of Q body is a repeating unit in which all of the four bonds of a silicon atom are each bonded to an oxygen atom, and corresponds to a repeating unit represented by Formula (c4).

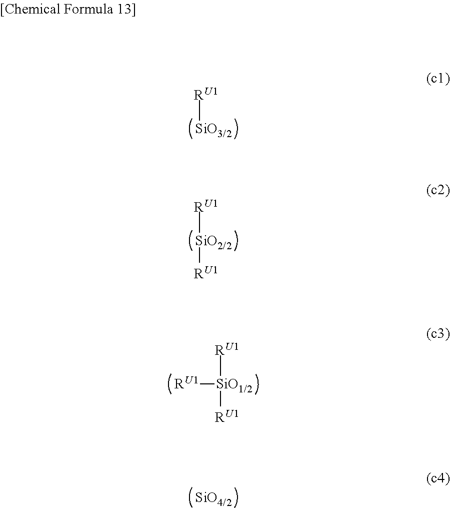

R^{U1} in Formula (c1), Formula (c2), and Formula (c3) represents a hydrogen atom or a monovalent organic group. R^{U1} in Formula (c1), Formula (c2), and Formula (c3) is as defined for R^{T1} in Formula (b1), Formula (b2), and Formula (b3), and its preferable embodiment is also the same.

Specific examples of the other repeating unit are shown below, but not limited thereto.

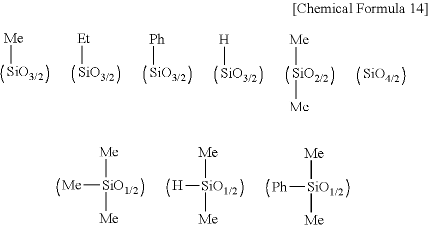

The specific siloxane polymer has a weight average molecular weight of preferably 500 to 50,000, more preferably 700 to 30,000, and even more preferably 1,000 to 20,000.

The specific siloxane polymer has a degree of dispersion of preferably 1.0 to 4.0 and more preferably 1.5 to 3.0.

The specific siloxane polymer has an acid value of preferably 50 to 300 mgKOH/g, more preferably 60 to 250 mgKOH/g, even more preferably 70 to 200 mgKOH/g, and particularly preferably 90 to 180 mgKOH/g.

The specific siloxane polymer has a double bond equivalent (also referred to as “C═C value”) of preferably 2.0 to 10.0 mmol/g, more preferably 3.0 to 7.0 mmol/g, and even more preferably 3.5 to 6.0 mmol/g. The C═C value of the specific siloxane polymer can be measured by iodine titration.

Preferably, the specific siloxane polymer does not have a structure in which a hydrogen atom of a carboxy group is substituted with an acid labile group.

An acid labile group is typically a protective group of a carboxy group and is a group (leaving group) that is eliminated by action of an acid.

Examples of the acid labile group include a group known as an acid labile group of a carboxy group, as exemplified by a tertiary alkyl group and a trialkylsilyl group.

A structure in which a hydrogen atom of a carboxy group is substituted with an acid labile group is typically represented by —COOR^{N} (where R^{N} represents an acid labile group). In other words, the specific siloxane polymer preferably does not contain a group represented by —COOR^{N}.

### <Method of Synthesizing Specific Siloxane Polymer>

The specific siloxane polymer can be synthesized by a known method. A method of synthesizing the specific siloxane polymer is described below by using as examples siloxane polymers having the repeating units represented by Formula (a1), Formula (a1a), and Formula (a1b) described above.

The siloxane polymers having the repeating units represented by Formula (a1), Formula (a1a), and Formula (a1b) described above can be respectively synthesized by, for example, subjecting compounds represented by Formula (a1z), Formula (a1az), and Formula (a1bz) to hydrolysis and polycondensation reaction.

It should be noted that X, n, X1, and X2 in Formula (a1z), Formula (a1az), and Formula (a1bz) below are as defined for those in Formula (a1), Formula (a1a), and Formula (a1b), and their preferable embodiments are also the same.

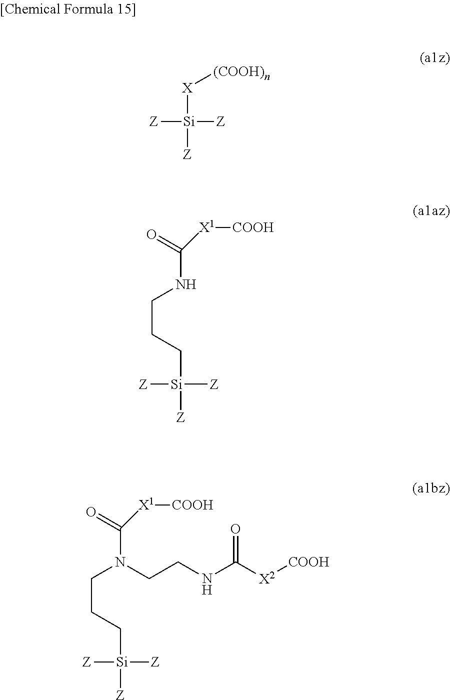

In Formula (a1z), Formula (a1az), and Formula (a1bz), Z represents a hydrolyzable group.

The hydrolyzable group represented by Z is preferably an alkoxy group, a halogen atom, or an acetoxy group, and more preferably an alkoxy group.

The alkoxy group is preferably an alkoxy group having 2 to 6 carbon atoms and more preferably a methoxy group or an ethoxy group.

The compounds represented by Formula (a1az) and Formula (a1bz) can be synthesized by, for instance, reacting 3-aminopropyltrialkoxysilane, 3-(2-aminoethyl)aminopropyltrialkoxysilane, or the like, with a dibasic acid anhydride (e.g., succinic anhydride, maleic anhydride, phthalic anhydride, itaconic anhydride, and tetrahydrophthalic anhydride).

The siloxane polymers having the repeating units represented by Formula (a1a) and Formula (a1b) described above can also be synthesized by another synthesis method in addition to the foregoing method.

Examples of another synthesis method include a method in which a compound represented by Formula (a1aa) or Formula (a1bb) is subjected to hydrolysis and polycondensation reaction to thereby synthesize a polysiloxane having an amino group, and then the obtained polysiloxane is reacted with a dibasic acid anhydride.

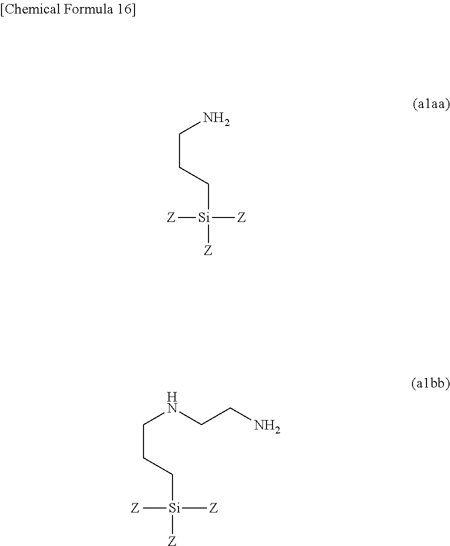

Z in Formula (a1aa) and Formula (a1bb) above is as defined for that in Formula (a1az) and Formula (a1bz), and its preferable embodiment is also the same.

The specific siloxane polymer may be used singly or in combination of two or more types thereof.

The lower limit value of the specific siloxane polymer content is preferably 5.0 mass % or more and more preferably 10.0 mass % or more with respect to the total solid content of the photosensitive composition. The upper limit value of the specific siloxane polymer content is preferably 99.0 mass % or less and more preferably 98.0 mass % or less with respect to the total solid content of the photosensitive composition. When two or more types of the specific siloxane polymer are contained in the photosensitive composition, it is preferable that the total content thereof fall within the foregoing numerical range.

When the photosensitive composition contains a filler, the specific siloxane polymer content is preferably 5.0 to 70.0 mass %, more preferably 5.0 to 50.0 mass %, more preferably 5.0 to 40.0 mass %, even more preferably 5.0 to 35.0 parts by mass, and particularly preferably 15.0 to 35.0 parts by mass with respect to the total solid content of the photosensitive composition. When the photosensitive composition does not contain a filler, the specific siloxane polymer content is preferably 75.0 mass % or more and more preferably 80.0 mass % or more with respect to the total solid content of the photosensitive composition.

### [Compound β]

The photosensitive composition contains the compound β.

The compound β is a compound different from the foregoing components.

The compound β is a compound having a structure that allows the amount of the carboxy group included in the specific siloxane polymer to reduce upon exposure (hereinafter also simply called “specific structure S0”).

The specific structure S0 is a structure that exhibits the action of reducing the amount of the carboxy group included in the specific siloxane polymer upon exposure. The specific structure S0 is preferably a structure that transitions from a ground state to an excited state upon exposure and exhibits the action of reducing carboxy groups included in the specific siloxane polymer in the excited state.

Examples of the specific structure S0 include a structure capable of accepting an electron from a carboxy group included in the specific siloxane polymer in a photoexcited state (hereinafter also called “specific structure S1”).

The specific structure S0 included in the compound β may be the overall structure constituting the entire compound β or a partial structure constituting a part of the compound β.

The compound β may be a low-molecular-weight compound or a high-molecular-weight compound and is preferably a low-molecular-weight compound. When the compound β is a low-molecular-weight compound, the low-molecular-weight compound preferably does not have a repeating unit.

When the compound β is a low-molecular-weight compound, the molecular weight of the compound β is preferably less than 5,000, more preferably less than 1,000, even more preferably 65 to 300, and particularly preferably 75 to 250.

The specific structure S0 is preferably the structure (specific structure S1) capable of accepting an electron from a carboxy group included in the specific siloxane polymer in a photoexcited state. In other words, the compound β is preferably a compound β having the structure (specific structure S1) capable of accepting an electron from a carboxy group included in the specific siloxane polymer in a photoexcited state. Probably, owing to the compound β, a carboxy group included in the specific siloxane polymer can be eliminated (decarboxylated) as CO₂.

Specific examples of the specific structure S0 include an aromatic ring as described later; in particular, a heteroaromatic ring is preferred, and a nitrogen-containing aromatic ring is more preferred.

The compound β is preferably an aromatic compound having an aromatic ring as the specific structure S0, more preferably a heteroaromatic compound having a heteroaromatic ring as the specific structure S0, and even more preferably a nitrogen-containing aromatic compound having a heteroaromatic ring as the specific structure so because the pattern formability is more excellent. That is, the specific structure S0 is preferably an aromatic ring, more preferably a heteroaromatic ring, and even more preferably a nitrogen-containing aromatic ring.

The aromatic compound is a compound having one or more aromatic rings. The nitrogen-containing aromatic compound is a compound having a heteroaromatic ring having one or more (e.g., 1 to 4) nitrogen atoms as ring member atoms.

Only one aromatic ring or plural aromatic rings may be present in the compound β. When plural aromatic rings are present, the aromatic rings may be present, for instance, at a side chain of a resin.

In the compound β, the aromatic ring is usable as the structure (specific structure S0) that allows the amount of the carboxy group included in the specific siloxane polymer to reduce upon exposure.

The aromatic ring may be a monocycle or a polycycle and is preferably a polycycle. The polycyclic aromatic ring is, for example, an aromatic ring in which plural (e.g., 2 to 5) aromatic ring structures are fused, and at least one of the plural aromatic ring structures preferably has a heteroatom as a ring member atom.

The aromatic ring may be a heteroaromatic ring, preferably has one or more (e.g., 1 to 4) heteroatoms (e.g., nitrogen atom, oxygen atom, sulfur atom, and the like) as ring member atoms, and more preferably has one or more (e.g., 1 to 4) nitrogen atoms as ring member atoms.

The number of ring member atoms of the aromatic ring is preferably 5 or 15.

The above-described aromatic ring of the compound β is preferably a polycycle (polycyclic aromatic ring) because the molar absorption coefficient with respect to light at a wavelength of 365 nm is higher. The number of monocyclic aromatic rings (the number of fused rings) in the polycyclic aromatic ring is preferably 2 or more and, because the molar absorption coefficient with respect to light at a wavelength of 365 nm is higher, more preferably 3 or more. The upper limit value thereof is preferably 6 or less.

Further, the polycyclic aromatic ring preferably has a heteroatom (e.g., nitrogen atom, oxygen atom, sulfur atom, and the like) as a ring member atom (in other words, is preferably a polycyclic heteroaromatic ring).

Examples of the aromatic ring included in the compound β include: monocyclic aromatic rings such as a pyridine ring, a pyrazine ring, a pyrimidine ring, and a triazine ring; aromatic rings in which two rings are fused, such as a quinoline ring, an isoquinoline ring, a quinoxaline ring, and a quinazoline ring; and aromatic rings in which three rings are fused, such as an acridine ring, a benzo[f]quinoline ring, a benzo[h]quinoline ring, a phenanthridine ring (benzo[c]quinoline ring), a benzo[h]isoquinoline ring, a phenanthroline ring, and a phenazine ring.

The aromatic ring may have one or more (e.g., 1 to 5) substituents.

Examples of the substituent include an alkyl group, an aryl group, a halogen atom, an acyl group, an alkoxycarbonyl group, an arylcarbonyl group, a carbamoyl group, a hydroxy group, a cyano group, and a nitro group. When the aromatic ring has two or more substituents, the plural substituents may be bonded together to form a non-aromatic ring.

In addition, it is also preferable that the aromatic ring be directly bonded to a carbonyl group to form an aromatic carbonyl group in the compound β. It is also preferable that plural aromatic rings be bonded via a carbonyl group.

It is also preferable that the aromatic ring is bonded to an imide group to form an aromatic imide group in the compound β. The imide group in the aromatic imide group may or may not form an imide ring together with the aromatic ring.

When plural (e.g., 2 to 5) aromatic rings form a series of aromatic ring structures bonded together by a structure selected from the group consisting of a single bond, a carbonyl group, and a multiple bond (e.g., a vinylene group which may have a substituent, —C═C—, —N═N—, and the like), the entire series of aromatic ring structures is regarded as one specific structure.

In addition, it is preferable that one or more of plural aromatic rings constituting the series of aromatic ring structures be the heteroaromatic rings.

The compound β is preferably a compound satisfying one or more of Requirement (1) to Requirement (4), more preferably satisfies at least one of Requirement (1) and Requirement (2), and even more preferably satisfies at least Requirement (1) and Requirement (2) (i.e., the compound β is a polycyclic heteroaromatic ring) because the pattern formability is more excellent. As a heteroatom included in the heteroaromatic ring, at least a nitrogen atom is preferably included.
Requirement (1): having a polycyclic aromatic ring
Requirement (2): having a heteroaromatic ring
Requirement (3): having an aromatic carbonyl group
Requirement (4): having an aromatic imide group

Other preferred embodiments of the compound β include, for instance, an acridinium salt, an (iso)quinolinium salt, and an iridium complex. The (iso)quinolinium salt refers to a quinolinium salt and an isoquinolinium salt.

For the compound β, the function of the compound β may be exhibited by action of two compounds. Examples of such two compounds include a combination of an aromatic compound (b1) unsubstituted or substituted with an electron donating group (preferably an alkyl group or an alkoxy group) and an aromatic compound (b2) substituted with an electron withdrawing group (preferably a cyano group or an alkoxycarbonyl group). With this combination, an electron is transferred from the photo-excited aromatic compound (b1) to the aromatic compound (b2), so that a cation radical of the aromatic compound (b1) is generated, and the cation radical accepts an electron from a carboxy group; thus, the function of the compound β is exhibited.

As the compound β, one or more selected from the group consisting of acridine, benzo[f]quinoline, benzo[h]quinoline, phenanthridine, benzo[h]isoquinoline, phenanthroline, and phenazine are preferred because the molar absorption coefficient with respect to light at a wavelength of 365 nm is higher and the photosensitivity with respect to light at a wavelength of 365 nm is excellent. These compounds may further have a substituent. The substituent is preferably an alkyl group, an aryl group, a halogen atom, an acyl group, an alkoxycarbonyl group, an arylcarbonyl group, a carbamoyl group, a hydroxy group, a cyano group, or a nitro group.

When the compound β is a resin, this may be a resin in which the specific structure S0 is bonded to the main chain of the resin via a single bond or a linking group.

The compound β that is a resin is obtained by polymerizing a monomer having a polycyclic heteroaromatic ring (e.g., a vinyl polycyclic heteroaromatic monomer and/or a (meth)acrylate monomer having the specific structure S0 (preferably a polycyclic heteroaromatic ring)). The monomer may optionally be copolymerized with another monomer.

The molar absorption coefficient of the compound β with respect to light at a wavelength of 365 nm is preferably 100 L/(mol·cm) or more, more preferably 500 L/(mol·cm) or more, even more preferably more than 1,000 L/(mol·cm), and particularly preferably 4,000 L/(mol cm) or more because the pattern formability is more excellent. The upper limit value thereof is preferably 20,000 L/(mol·cm) or less.

It should be noted that the molar absorption coefficient with respect to light at a wavelength of 365 nm above is a molar absorption coefficient measured by dissolving the compound β in acetonitrile. When the compound β does not dissolve in acetonitrile, a solvent used to dissolve the compound β may be changed as needed.

The molar absorption coefficient of the compound β falling within the foregoing range is advantageous particularly when a photosensitive layer is exposed through a temporary support (preferably a PET film). In other words, since the absorption coefficient is adequately small, the generation of bubbles due to decarboxylation can be controlled even when exposure is performed through a temporary support, thus preventing the deterioration in a pattern shape.

Exemplary compounds having such a high molar absorption coefficient with respect to light at a wavelength of 365 nm include a compound in which three or more aromatic rings are fused to form an aromatic ring. Examples of the compound in which three or more aromatic rings are fused to form an aromatic ring include the above-listed compounds.

Examples of the compound β include: monocyclic aromatic compounds such as pyridine, 5,6,7,8-tetrahydroquinoline, 4-acetylpyridine, 4-benzoylpyridine, pyrazine, pyrimidine, and triazine; compounds in which two rings are fused to form an aromatic ring, such as quinoline, 2,4-dimethylquinoline, quinoline, isoquinoline, 1-methylisoquinoline, 1-phenylisoquinoline, quinoxaline, and quinazoline; and compounds in which three or more rings are fused to form an aromatic ring, such as acridine, 9-methylacridine, benzo[f]quinoline, benzo[h]quinoline, phenanthridine, benzo[h]isoquinoline, phenanthroline, and phenazine.

These compounds may further have a substituent. The substituent is preferably an alkyl group, an aryl group, a halogen atom, an acyl group, an alkoxycarbonyl group, an arylcarbonyl group, a carbamoyl group, a hydroxy group, a cyano group, or a nitro group.

The compound β preferably includes at least one selected from the group consisting of acridine, 9-alkylacridine (preferably 9-methylacridine), 9-phenylacridine, quinoline, 2,4-dialkylquinoline (preferably 2,4-dimethylquinoline), isoquinoline, and 1-alkylisoquinoline (preferably 2-methylquinoline).

The compound β may be used singly or in combination of two or more types thereof.

The compound β content is preferably 0.1 mass % or more and more preferably 1.0 mass % or more with respect to the total solid content of the photosensitive composition because the pattern formability is more excellent. The upper limit value thereof is preferably 80.0 mass % or less, more preferably 60.0 mass % or less, even more preferably 30.0 mass % or less, particularly preferably 20.0 mass % or less, and most preferably 15.0 mass % or less with respect to the total solid content of the photosensitive composition. When two or more types of the compound β are contained in the photosensitive composition, it is preferable that the total content thereof fall within the foregoing numerical range.

The total number of the specific structures S0 included in the compound β is preferably 1 mol % or more, more preferably 3 mol % or more, even more preferably 5 mol % or more, and particularly preferably 10 mol % or more with respect to the total number of carboxy groups included in the specific siloxane polymer because the pattern formability is more excellent. The upper limit value thereof is preferably 200 mol % or less, more preferably 100 mol % or less, and even more preferably 80 mol % or less with respect to the total number of carboxy groups included in the specific siloxane polymer from the viewpoint of quality of a film to be obtained.

### [Filler]

The photosensitive composition preferably contains a filler.

When the photosensitive composition contains a filler, the coefficient of thermal expansion and the average dielectric loss tangent of the resulting cured film are more excellent.

Examples of the filler include an organic filler and an inorganic filler, and an inorganic filler is preferable.

Examples of the filler include: silicon dioxide (silica); silicates such as kaolinite, kaolin clay, calcined clay, talc, and a glass filler such as undoped glass; and alumina, barium sulfate, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, calcium zirconate, zirconium phosphate, cordierite, zirconium tungstate, and manganese nitride.

The filler preferably includes at least one selected from the group consisting of silicon dioxide (silica), boron nitride, barium sulfate, and silicate, and more preferably includes silicon dioxide (silica).

The shape of the filler may be spherical or non-spherical (for example, a crushed shape and a fibrous shape), and a spherical shape is preferable.

The filler may be subjected to a surface treatment. Examples of the surface treatment include a treatment of introducing a functional group and a treatment using a known surface modifier. Examples of the functional group include a polymerizable group (e.g., a polymerizable group included in a polymerizable compound to be described later) and a hydrophobic group.

Examples of the surface modifier include known surface modifiers such as a silane coupling agent, a titanate-based coupling agent, and a silazane compound.

Examples of the filler include Sea Foster KE-S30 (manufactured by Nippon Shokubai Co., Ltd., silicon dioxide, solid concentration of 100 mass %), NHM-3N (manufactured by TOKUYAMA CORPORATION, silicon dioxide, solid concentration of 100 mass %), YA050C-MJE (manufactured by Admatechs Co., Ltd., silicon dioxide, MEK slurry with solid concentration of 50 mass %), SFP-20M (manufactured by Denka Company Limited, silicon dioxide), SO-C series (e.g., SO-C2, manufactured by Admatechs Co., Ltd., silicon dioxide), SO-E series (e.g., SO-E2, manufactured by Admatechs Co., Ltd., silicon dioxide), PMA-ST (manufactured by NISSAN CHEMICAL CORPORATION, silicon dioxide), MEK-ST-L (manufactured by NISSAN CHEMICAL CORPORATION, silicon dioxide), MEK-AC-5140Z (manufactured by NISSAN CHEMICAL CORPORATION, silicon dioxide), MEK-EC-2430Z (manufactured by NISSAN CHEMICAL CORPORATION, solid concentration of 30 mass %), barium sulfate (manufactured by SOLVAY SPECIALTY CHEMICALS JAPAN, solid concentration of 100 mass %), NHM-5N (manufactured by TOKUYAMA CORPORATION, silicon dioxide, solid concentration of 100 mass %), Y50SP-AM1 (manufactured by Admatechs Co., Ltd., silicon dioxide, MEK slurry with solid concentration of 50 mass %), and Y50SZ-AM1 (manufactured by Admatechs Co., Ltd., silicon dioxide, MEK slurry with solid concentration of 50 mass %).

The average particle size of the filler is preferably 500 nm or less, more preferably 300 nm or less, and even more preferably 100 nm or less. The lower limit value thereof is preferably more than 0 nm and more preferably 5 nm or more. The average particle size of the filler is also preferably 5 to 100 nm.

The average particle size of the filler can be calculated by the following particle size measurement method.

Particle size measurement method: a coating liquid containing the filler is applied onto a substrate to form a coating film; the operation in which a rectangular region of 3 μm×10 μm on a cross section extending along the normal direction to the surface of the coating film is observed with a scanning electron microscope and the major axes of all particles of the filler observed within the above region are measured, is carried out for five different places in the coating film; and the average of the major axes of all particles of the filler in the five places as measured by the operation is determined as the average particle size of the filler. The coating liquid may be the photosensitive composition according to the embodiment of the present invention.

The procedures of the particle size measurement method are described in detail.

First, a coating liquid containing the filler is applied onto a substrate to form a coating film. The thickness of the coating film is preferably 3 μm or more. The substrate used is a glass substrate. When the coating film is formed, a drying treatment may optionally be performed.

A cross section extending along the normal direction to the surface (on the side opposite to the substrate side) of the obtained coating film is cut out, and a rectangular region of 3 μm×10 μm on the cross section is observed with a scanning electron microscope to measure the major axes of all particles of the filler observed within the region. The scanning electron microscope used is, for instance, S-4800 manufactured by Hitachi High-Tech Corporation. The magnification for the observation is 50,000×.

The operation above is carried out for five different places in the coating film, and the average (arithmetic mean) of the major axes of all particles of the filler in the five places as measured by the operation is determined as the average particle size of the filler.

The major axis (axes) above refers to the length of the longest line segment among line segments each of which connects any two points on the outline of a particle of the filler in an observation image.

When particles of the filler agglomerate to form an agglomerate in an observation image, the major axes of the respective particles of the filler forming the agglomerate are measured.

The refractive index of the filler is preferably 0.5 to 3.0 and more preferably 1.2 to 1.8.

The filler may be used singly or in combination of two or more types thereof.

The filler content is usually 10.0 mass % or more, preferably 30.0 mass % or more, more preferably 50.0 mass % or more, even more preferably 60.0 mass % or more, particularly preferably 65.0 mass % or more, and most preferably 70.0 mass % or more with respect to the total solid content of the photosensitive composition. The upper limit value thereof is preferably 90.0 mass % or less, more preferably 80.0 mass % or less, and even more preferably 75.0 mass % or less with respect to the total solid content of the photosensitive composition. When two or more types of the filler are contained in the photosensitive composition, it is preferable that the total content thereof fall within the foregoing numerical range.

### [Polymerizable Compound]

The photosensitive composition preferably contains a polymerizable compound.

The polymerizable compound is a compound different from the foregoing components.

The polymerizable compound is a compound having one or more polymerizable groups per molecule.

Examples of the polymerizable group included in the polymerizable compound include a (meth)acryloyl group, a vinyl group, and a styryl group, with a (meth)acryloyl group being preferred, and a methacryloyl group being more preferred.

Examples of the polymerizable compound include a polymerizable compound having one polymerizable group per molecule (hereinafter also referred to as “monofunctional polymerizable compound”), a polymerizable compound having two polymerizable groups per molecule (hereinafter also referred to as “bifunctional polymerizable compound”), and a polymerizable compound having three or more polymerizable groups per molecule (hereinafter also referred to as “tri- or higher functional polymerizable compound”).

As the polymerizable compound, a bifunctional polymerizable compound is preferred.

The upper limit value of the number of functional groups of the polymerizable compound is not particularly limited and is preferably 10 or less, more preferably 8 or less, and even more preferably 5 or less; because the effect of the present invention is more excellent, the upper limit value is particularly preferably 4 or less, and most preferably 2.

Examples the bifunctional polymerizable compound include polyethylene glycol di(meth)acrylate, tricyclodecane dimethanol di(meth)acrylate, 1,9-nonanediol di(meth)acrylate, and 1,6-hexanediol di(meth)acrylate. Exemplary commercial products of the bifunctional polymerizable compound include diethylene glycol dimethacrylate (2G, manufactured by Shin-Nakamura Chemical Co., Ltd.), triethylene glycol dimethacrylate (3G, manufactured by Shin-Nakamura Chemical Co., Ltd.), polyethylene glycol #200 dimethacrylate (4G, manufactured by Shin-Nakamura Chemical Co., Ltd.), tricyclodecane dimethanol diacrylate (A-DCP, manufactured by Shin-Nakamura Chemical Co., Ltd.), tricyclodecane dimethanol dimethacrylate (DCP, manufactured by Shin-Nakamura Chemical Co., Ltd.), 1,9-nonanediol diacrylate (A-NOD-N, manufactured by Shin-Nakamura Chemical Co., Ltd.), and 1,6-hexanediol diacrylate (A-HD-N, manufactured by Shin-Nakamura Chemical Co., Ltd.).

Examples of the tri- or higher functional polymerizable compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

The “(tri/tetra/penta/hexa) (meth)acrylate” is a concept covering tri(meth)acrylate, tetra(meth)acrylate, penta(meth)acrylate, and hexa (meth)acrylate, and the “(tri/tetra) (meth)acrylate” is a concept covering tri(meth)acrylate and tetra(meth)acrylate.

Exemplary commercial products of the polymerizable compound also include a caprolactone-modified compound of a (meth)acrylate compound (KAYARAD (registered trademark) DPCA-20 or the like, manufactured by Nippon Kayaku Co., Ltd.; and A-9300-1CL or the like, manufactured by Shin-Nakamura Chemical Co., Ltd.), an alkylene oxide-modified compound of a (meth)acrylate compound (KAYARAD RP-1040 or the like, manufactured by Nippon Kayaku Co., Ltd.; ATM-35E, A-9300, or the like, manufactured by Shin-Nakamura Chemical Co., Ltd.; and EBECRYL (registered trademark) 135 or the like, manufactured by Daicel-Allnex Ltd.), and ethoxylated glycerin triacrylate (A-GLY-9E or the like, manufactured by Shin-Nakamura Chemical Co., Ltd.).

Examples of the polymerizable compound also include urethane (meth)acrylate (preferably, tri- or higher functional urethane (meth)acrylate). The number of polymerizable groups included in the urethane (meth)acrylate is preferably 6 or more and more preferably 8 or more. The upper limit value thereof is preferably 20 or less.

Examples of the tri- or higher functional urethane (meth)acrylate include: 8UX-015A (manufactured by Taisei Fine Chemical Co., Ltd.); UA-32P, U-15HA, and UA-1100H (all manufactured by Shin-Nakamura Chemical Co., Ltd.); AH-600 (manufactured by KYOEISHA CHEMICAL Co., LTD.); and UA-306H, UA-306T, UA-306I, UA-510H, and UX-5000 (all manufactured by Nippon Kayaku Co., Ltd.).

The polymerizable compound may be used singly or in combination of two or more types thereof.

The polymerizable compound content is preferably 30.0 mass % or less, more preferably 25.0 mass % or less, even more preferably 20.0 mass % or less, particularly preferably 15.0 mass % or less, and most preferably 10.0 mass % or less with respect to the total solid content of the photosensitive composition. The lower limit value thereof is preferably 1.0 mass % or more and more preferably 5.0 mass % or more with respect to the total solid content of the photosensitive composition. When two or more types of the polymerizable compound are contained in the photosensitive composition, it is preferable that the total content thereof fall within the foregoing numerical range.

### [Photopolymerization Initiator]

The photosensitive composition may contain a photopolymerization initiator.

The photopolymerization initiator is a compound different from the foregoing components.

Examples of the photopolymerization initiator include a photoradical polymerization initiator, a photocationic polymerization initiator, and a photoanionic polymerization initiator, with a photoradical polymerization initiator being preferred.

Examples of the photopolymerization initiator include an oxime ester compound (a photopolymerization initiator having an oxime ester structure), an aminoacetophenone compound (a photopolymerization initiator having an aminoacetophenone structure), a hydroxyacetophenone compound (a photopolymerization initiator having a hydroxyacetophenone structure), an acylphosphine oxide compound (a photopolymerization initiator having an acylphosphine oxide structure), and a bistriphenylimidazole compound (a photopolymerization initiator having a bistriphenylimidazole structure).

For the photopolymerization initiator, an oxime ester compound or an aminoacetophenone compound is preferred.

Examples of the oxime ester compound include 1,2-octanedione, 1-[4-(phenylthio)phenyl-, 2-(0-benzoyloxime)] (product name: IRGACURE OXE-01, manufactured by BASF), etanone, 1-[9-ethyl-6-(2-methylbenzoyl)-9H-carbazol-3-yl]-, 1-(O-acetyloxime) (product name: IRGACURE OXE-02, manufactured by BASF), [8-[5-(2,4,6-trimethylphenyl)-11-(2-ethylhexyl)-11H-benzo[a]carbazoyl][2-(2,2,3,3-tetrafluoropropoxy)phenyl]methanone-(O-acetyloxime) (product name: IRGACURE OXE-03, manufactured by BASF), 1-[4-[4-(2-benzofuranylcarbonyl)phenyl]thio]phenyl]-4-methylpentanone-1-(0-acetyloxime) (product name: IRGACURE OXE-04, manufactured by BASF, and product name: Lunar 6, manufactured by DKSH), 1-[4-(phenylthio)phenyl]-3-cyclopentylpropan-1,2-dione-2-(0-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by Changzhou Tronly New Electronic Materials Co., Ltd.).

Examples of the aminoacetophenone compound include 2-(dimethylamino)-2-[(4-methylphenyl)methyl]-1-[4-(4-morpholinyl)phenyl]-1-butanone (product name: Omnirad 379EG, Omnirad series, manufactured by IGM Resins B.V.), 2-methyl-1-(4-methylthiophenyl)-2-morpholinopropan-1-one (product name: Omnirad 907), and APi-307 (1-(biphenyl-4-yl)-2-methyl-2-morpholinopropan-1-one, manufactured by Shenzhen UV-ChemTech Co., Ltd.).

Examples of the photopolymerization initiator include 2-hydroxy-1-{4-[4-(2-hydroxy-2-methyl-propionyl)-benzyl]phenyl}-2-methyl-propan-1-one (product name: Omnirad 127), 2-benzyl-2-dimethylamino-1-(4-morpholinophenyl)-butanone-1 (product name: Omnirad 369), 2-hydroxy-2-methyl-1-phenyl-propan-1-one (product name: Omnirad 1173), 1-hydroxy-cyclohexyl-phenyl-ketone (product name: Omnirad 184), 2,2-dimethoxy-1,2-diphenylethane-1-one (product name: Omnirad 651), 2,4,6-trimethylbenzoyl-diphenylphosphine oxide (product name: Omnirad TPO H), and bis(2,4,6-trimethylbenzoyl)phenylphosphine oxide (product name: Omnirad 819).

Examples of the photopolymerization initiator also include those described in paragraphs 0031 to 0042 of JP2011-095716A and paragraphs 0064 to 0081 of JP2015-014783A.

The photopolymerization initiator may be used singly or in combination of two or more types thereof.

The photopolymerization initiator content is preferably 10.0 mass % or less, more preferably 5.0 mass % or less, and even more preferably 2.0 mass % or less with respect to the total solid content of the photosensitive composition. The lower limit value thereof is preferably 0.1 mass % or more and more preferably 0.5 mass % or more with respect to the total solid content of the photosensitive composition. When two or more types of the photopolymerization initiator are contained in the photosensitive composition, it is preferable that the total content thereof fall within the foregoing numerical range.

### [Surfactant]

The photosensitive composition may contain a surfactant. The surfactant is a compound different from the foregoing components.

Examples of the surfactant include an anionic surfactant, a cationic surfactant, a nonionic surfactant, and an amphoteric surfactant, and a nonionic surfactant is preferable.

Examples of the nonionic surfactant include a fluorine-based surfactant, a hydrocarbon-based surfactant, and a silicone-based surfactant. The surfactant is preferably free of a fluorine atom in terms of the improvement in environmental appropriateness. For the surfactant, a hydrocarbon-based surfactant or a silicone-based surfactant is preferred.

Exemplary commercially products of the fluorine-based surfactant include: MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, and F-780 (all of which are manufactured by DIC Corporation); EXP.MFS-324, EXP.MFS-330, EXP.MFS-578, EXP.MFS-578-2, EXP.MFS-579, EXP.MFS-586, EXP.MFS-587, EXP.MFS-628, EXP.MFS-631, EXP.MFS-603, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730 LM, 650AC, 681, and 683 (all of which are manufactured by NEOS COMPANY LIMITED); and U-120E (manufactured by Uni-chem Co., Ltd.).

Examples of the fluorine-based surfactant include an acrylic compound which has a functional group containing a fluorine atom and in which, by applying heat, the functional group containing a fluorine atom is broken to volatilize a fluorine atom. Examples of such a fluorine-based surfactant include MEGAFACE DS series (manufactured by DIC Corporation, MEGAFACE DS-21 or the like in the Chemical Daily (Feb. 22, 2016) and Nikkei Business Daily (Feb. 23, 2016)).

The fluorine-based surfactant may be a polymer of a fluorine atom-containing vinyl ether compound having a fluorinated alkyl group or a fluorinated alkylene ether group, and a hydrophilic vinyl ether compound. The fluorine-based surfactant may be a block polymer.

The fluorine-based surfactant may be a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups).

Examples of the fluorine-based surfactant also include a fluorine-containing polymer having an ethylenically unsaturated group-containing group in the side chain. Specific examples thereof include MEGAFACE RS-101, RS-102, RS-718K, and RS-72-K (all manufactured by DIC Corporation).

For the fluorine-based surfactant, a surfactant derived from an alternative material for perfluorooctanoic acid (PFOA), perfluorooctanesulfonic acid (PFOS), or such a compound having a linear perfluoroalkyl group having 7 or more carbon atoms is preferred in terms of the improvement in environmental appropriateness.

Examples of the hydrocarbon-based surfactant include glycerol, trimethylolpropane, trimethylolethane, ethoxylate and propoxylate thereof (e.g., glycerol propoxylate and glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and sorbitan fatty acid ester.

Examples of the hydrocarbon-based surfactant include: PLURONIC (registered trademark) L10, L31, L61, L62, 10R5, 17R2, and 25R2, TETRONIC 304, 701, 704, 901, 904, and 150R1, and HYDROPALAT WE 3323 (all of which are manufactured by BASF); SOLSPERSE 20000 (manufactured by Lubrizol Corporation); NCW-101, NCW-1001, and NCW-1002 (all of which are manufactured by FUJIFILM Wako Pure Chemical Corporation); PIONIN D-1105, D-6112, D-6112-W, and D-6315 (all of which are manufactured by Takemoto Oil&Fat Co., Ltd.); and OLFINE E1010 and SURFYNOL 104, 400, and 440 (all of which are manufactured by Nissin Chemical Co., Ltd.).

Examples of the silicone-based surfactant include a linear polymer consisting of a siloxane bond, a modified siloxane polymer with an organic group introduced in the side chain and/or the terminal, and a polymer having a repeating unit having a hydrophilic group in the side chain and a repeating unit having a siloxane bond-containing group in the side chain. For the silicone-based surfactant, a polymer having a repeating unit having a hydrophilic group in the side chain and a repeating unit having a siloxane bond-containing group in the side chain is preferred. The polymer may be a random copolymer or a block copolymer.

The repeating unit having a siloxane bond-containing group in the side chain is preferably a repeating unit represented by Formula (SX1) or a repeating unit represented by Formula (SX2).

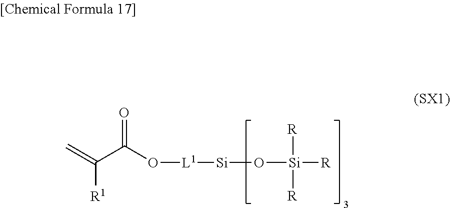

In Formula (SX1), R's each independently represent an alkyl group having 1 to 3 carbon atoms. R¹ represents a hydrogen atom or a methyl group. L¹ represents a single bond or a divalent organic group.

A plurality of R's may be the same or different.

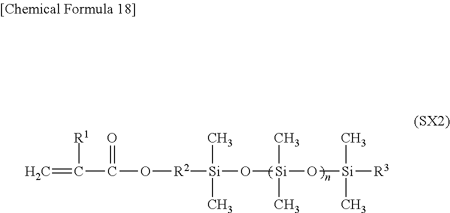

In Formula (SX2), R¹ represents a hydrogen atom or a methyl group. R² represents an alkylene group having 1 to 10 carbon atoms. R³ represents an alkyl group having 1 to 4 carbon atoms. n represents an integer of 5 to 50.

The repeating unit having a hydrophilic group in the side chain is preferably a repeating unit represented by Formula (SX3).

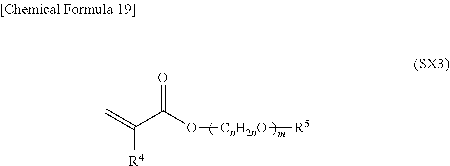

In Formula (SX3), R⁴ and R⁵ each independently represent a hydrogen atom or a methyl group. n represents an integer of 1 to 4. m represents an integer of 1 to 100.

Examples of the silicone-based surfactant include EXP. S-309-2, EXP.S-315, EXP.S-503-2, and EXP.S-505-2 (all of which are manufactured by DIC Corporation); DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.); X-22-4952, X-22-4272, X-22-6266, KF-351A, K354L, KF-355A, KF-945, KF-640, KF-642, KF-643, X-22-6191, X-22-4515, KF-6004, KF-6001, KF-6002, KP-101, KP-103, KP-104, KP-105, KP-106, KP-109, KP-109, KP-112, KP-120, KP-121, KP-124, KP-125, KP-301, KP-306, KP-310, KP-322, KP-323, KP-327, KP-341, KP-368, KP-369, KP-611, KP-620, KP-621, KP-626, and KP-652 (all of which are manufactured by Shin-Etsu Silicone Co., Ltd.); F-4440, TSF-4300, TSF-4445, TSF-4460, and TSF-4452 (all of which are manufactured by Momentive Performance Materials Co., Ltd.); and BYK300, BYK306, BYK307, BYK310, BYK320, BYK323, BYK 325, BYK330, BYK313, BYK315N, BYK331, BYK333, BYK345, BYK347, BYK348, BYK349, BYK370, BYK377, BYK378, and BYK 323 (all of which are manufactured by BYK Chemie).

Examples of the surfactant also include those described in paragraph 0017 of JP04502784B and paragraphs 0060 to 0071 of JP2009-237362A.

The surfactant may be used singly or in combination of two or more types thereof.

The surfactant content is preferably 0.0001 to 10.0 mass %, more preferably 0.001 to 5.0 mass %, and even more preferably 0.005 to 3.0 mass % with respect to the total solid content of the photosensitive composition. When two or more types of the surfactant are contained in the photosensitive composition, it is preferable that the total content thereof fall within the foregoing numerical range.

### [Other Additives]

The photosensitive composition may contain other additives in addition to the foregoing components.

Examples of other additives include resins other than the specific siloxane polymer, triazole, benzotriazole, and tetrazole as well as their derivatives, an aliphatic thiol compound, a thermally crosslinkable compound, a polymerization inhibitor, a hydrogen donating compound, a solvent, an impurity, a plasticizer, a sensitizer, and an alkoxysilane compound.

Examples of the triazole, the benzotriazole, and the tetrazole as well as their derivatives, the aliphatic thiol compound, the thermally crosslinkable compound, the polymerization inhibitor, and the hydrogen donating compound include those described in WO2022/039027.

Examples of the plasticizer, the sensitizer, and the alkoxysilane compound include those described in paragraphs 0097 to 0119 of WO2018/179640A.

The solvent is not particularly limited as long as it allows for dissolution or dispersion of various components other than the solvent that may be contained in the photosensitive composition.

Examples of the solvent include water, an alkylene glycol ether solvent, an alkylene glycol ether acetate solvent, an alcohol solvent (e.g., methanol, or ethanol), a ketone solvent (e.g., acetone, or methyl ethyl ketone), an aromatic hydrocarbon solvent (e.g., toluene), a non-protic polar solvent (e.g., dimethyl sulfoxide, or sulfolane), an amide solvent, a cyclic ether solvent (e.g., tetrahydrofuran), an ester solvent (e.g., n-propyl acetate), an amide solvent (e.g., N, N-dimethylformamide, N, N-dimethylacetamide, N-methylpyrrolidone, or N-ethylpyrrolidone), a lactone solvent, and a mixed solvent containing two or more thereof.

The solvent may be used singly or in combination of two or more types thereof.

The solvent content is preferably 50 to 1900 parts by mass, more preferably 100 to 1200 parts by mass, and even more preferably 100 to 900 parts by mass with respect to 100 parts by mass of the total solid content of the photosensitive composition.

The photosensitive composition may contain impurities.

Exemplary impurities include sodium, potassium, magnesium, calcium, iron, manganese, copper, aluminum, titanium, chromium, cobalt, nickel, zinc, tin, halogen, and ions thereof. Since halide ions, sodium ions, and potassium ions are easily mixed as impurities, it is preferable that the content fall within the following range.

The impurity content is preferably 80 mass ppm or less, more preferably 10 mass ppm or less, and even more preferably 2 mass ppm or less with respect to the total solid content of the photosensitive composition. The lower limit value thereof is usually 0 mass ppb or more, may be 1 mass ppb or more, and may also be 0.1 mass ppm or more with respect to the total solid content of the photosensitive composition.

Examples of a method of adjusting the impurity content include a method in which raw materials having a low impurity content are used as raw materials of components that may be contained in the photosensitive composition, a method in which components that may be contained in the photosensitive composition are purified, and a method in which impurities are prevented from being mixed in during preparation of the photosensitive composition.

The impurity content can be measured by, for instance, inductively coupled plasma (ICP) emission spectroscopy, atomic absorption spectroscopy, ion chromatography, and other known methods.

In the photosensitive composition, it is preferable that the contents of such compounds as benzene, formaldehyde, trichlorethylene, 1,3-butadiene, carbon tetrachloride, chloroform, and hexane be low. Specifically, the contents of those compounds are each preferably 100 mass ppm or less, more preferably 20 mass ppm or less, and even more preferably 4 mass ppm or less with respect to the total solid content of the photosensitive composition. The lower limit value of each may be 10 mass ppb or more, and may also be 100 mass ppm or more with respect to the total solid content of the photosensitive composition.

The contents of those compounds are adjustable in the same manner as that for the impurities. The contents of those compounds can be measured by known measurement methods.

### <Acid Generator>

It is preferable that the photosensitive composition be substantially free of an acid generator.

Examples of the acid generator include a known compound used as an acid generator (i.e., a compound that generates an acid upon irradiation with light) in a photosensitive composition, as exemplified by an onium salt compound such as an arylsulfonium salt compound, a diazomethane derivative, and a glyoxime derivative.

For the phrase “substantially free of an acid generator,” it suffices if the acid generator content is less than 0.1 mass % with respect to the total solid content of the photosensitive composition, and 0.05 mass % or less is preferred.

### [Transfer Film]

A transfer film includes a temporary support and a photosensitive layer formed of the photosensitive composition described above.

A composition layer may further include an interlayer, a thermoplastic resin layer, and other layers in addition to the photosensitive layer. Hereinafter, the photosensitive layer and optionally included other layers are sometimes collectively called “composition layer.”

The transfer film may be configured to further include a cover film protecting a surface of the composition layer.

The FIGURE is a schematic cross-sectional view showing one example of an embodiment of the transfer film.

A transfer film 100 shown in the FIGURE has a configuration in which a temporary support 12, a photosensitive layer 14, and a cover film 16 are laminated in this order.

While the transfer film 100 in the embodiment shown in the FIGURE has the cover film 16, the transfer film 100 may be configured without the cover film 16.

The transfer film may further include an interlayer and/or a thermoplastic resin layer in addition to the photosensitive layer as the composition layer.

Each member included in the transfer film is described in detail below.

### [Temporary Support]

The transfer film includes the temporary support.

The temporary support is a member supporting the composition layer such as the photosensitive layer and is removed by a peeling treatment at the end.

The temporary support may be of a single layer structure or a multilayer structure.

The temporary support is preferably a film and more preferably a resin film.

For the temporary support, also preferred is a film that has flexibility and that does not remarkably deform, contract, or expand under pressure or under pressure and heat. Examples of the film include a polyethylene terephthalate film (e.g., biaxially stretched polyethylene terephthalate film), a polymethyl methacrylate film, a cellulose triacetate film, a polystyrene film, a polyimide film, and a polycarbonate film, with a polyethylene terephthalate film being preferred. The temporary support preferably has no deformation such as wrinkles and scratches.

The temporary support preferably has high transparency because this allows for pattern exposure through the temporary support. Specifically, the transmittance at all of a wavelength of 313 nm, a wavelength of 365 nm, a wavelength of 405 nm, and a wavelength of 436 nm is preferably 60% or more, more preferably 70% or more, even more preferably 80% or more, and particularly preferably 90% or more. The upper limit value thereof is preferably less than 100%. Favorable values of the transmittance at the wavelengths above are, for instance, 87%, 92%, and 98%.

Lower haze of the temporary support is preferred for the sake of the patternability during pattern exposure through the temporary support and the transparency of the temporary support. Specifically, a haze value of the temporary support is preferably 2% or less, more preferably 0.5% or less, and even more preferably 0.1% or less. The lower limit value thereof is preferably 0% or more.

A smaller number of fine particles, foreign substances, and defects included in the temporary support is preferred for the sake of the patternability during pattern exposure through the temporary support and the transparency of the temporary support. Specifically, the number of fine particles, foreign substances, and defects with a diameter of 1 μm or more in the temporary support is preferably 50 pieces/mm² or less, more preferably 10 pieces/mm² or less, even more preferably 3 pieces/mm² or less, and particularly preferably 0 pieces/mm².

Specific examples of the number of fine particles, foreign substances, and defects with a diameter of 1 μm or more in the temporary support include 2 pieces/mm² and 0 pieces/mm².

The thickness of the temporary support is preferably 5 to 200 μm, and from the viewpoint of ease of handling and general-purpose properties, more preferably 5 to 150 μm, even more preferably 5 to 50 μm, and particularly preferably 5 to 35 μm.

The thickness of the temporary support is an average of any five points measured by observation of a cross section with a scanning electron microscope (SEM).

The surface of the temporary support that is in contact with the composition layer may be modified by UV irradiation, corona discharge, plasma, and the like because the adhesion between the temporary support and the photosensitive layer can be improved.

When the surface is modified by UV irradiation, the amount of exposure in the UV irradiation is preferably 10 to 2,000 mJ/cm² and more preferably 50 to 1,000 mJ/cm².

Examples of a light source for the UV irradiation include a low pressure mercury lamp, a high pressure mercury lamp, a super high pressure mercury lamp, a carbon arc lamp, a metal halide lamp, a xenon lamp, a chemical lamp, an electrodeless discharge lamp, and a light emitting diode that emit light in a wavelength range of 150 to 450 nm.

The lamp output and the illuminance of a lamp are suitably adjustable.

Examples of the temporary support include a biaxially stretched polyethylene terephthalate film having a thickness of 16 μm, a biaxially stretched polyethylene terephthalate film having a thickness of 12 μm, and a biaxially stretched polyethylene terephthalate film having a thickness of 9 μm.

The temporary support may be a recycled product. The recycled product is for example obtained by cleaning a used film or the like, forming it into a chip, and then forming the obtained material into a film. Exemplary commercial products of the recycled product include Ecouse series (manufactured by Toray Industries, Inc.).

Examples of the temporary support include those described in paragraphs 0017 and 0018 of JP2014-085643A, paragraphs 0019 to 0026 of JP2016-027363A, paragraphs 0041 to 0057 of WO2012/081680, and paragraphs 0029 to 0040 of WO2018/179370, the contents of which are incorporated in the present specification.

The temporary support may have a layer (lubricant layer) containing fine particles on one or both surfaces of the temporary support in order to impart handleability. The fine particles contained in the lubricant layer preferably have a diameter of 0.05 to 0.8 μm. The thickness of the lubricant layer is preferably 0.05 to 1.0 μm.

Exemplary commercial products of the temporary support include: LUMIRROR 16FB40, LUMIRROR 16KS40, LUMIRROR #38-U48, LUMIRROR #75-U34, and LUMIRROR #25T60 (all of which are manufactured by Toray Industries, Inc.); and COSMOSHINE A4100, COSMOSHINE A4160, COSMOSHINE A4300, COSMOSHINE A4360, and COSMOSHINE A8300 (all of which are manufactured by TOYOBO Co., Ltd.).

### [Photosensitive Layer]

The photosensitive layer is a layer formed of the photosensitive composition described above.

Components that may be contained in the photosensitive layer are, for instance, as defined for the components that may be contained in the photosensitive composition, and their preferable embodiments are also the same.

It should be noted that a preferable numerical range of the content of each component in the photosensitive layer is the same as the preferable range where the “content (mass %) of each component with respect to the total solid content of the photosensitive composition” is changed to the “content (mass %) of each component with respect to the total mass of the photosensitive layer.” Specifically, the sentence “the specific siloxane polymer content is preferably 5.0 mass % or more with respect to the total solid content of the photosensitive composition” is changed to “the specific siloxane polymer content is preferably 5.0 mass % or more with respect to the total mass of the photosensitive layer.”

### <Thickness of Photosensitive Layer>

The average thickness of the photosensitive layer is preferably 0.5 to 40 μm, more preferably 0.5 to 25 μm, and even more preferably 3 to 20 μm. The average thickness of the photosensitive layer being 40 μm or less is preferable in terms of an excellent resolution of a pattern, and the average thickness of the photosensitive layer being 0.5 μm or more is preferable in terms of excellent reliability.

### [Interlayer and Thermoplastic Resin Layer]

The transfer film may include an interlayer and/or a thermoplastic resin layer.

Examples of the interlayer and the thermoplastic resin layer include those described in paragraphs 0164 to 0204 of WO2021/166719, the contents of which are incorporated herein.

### [Cover Film]

The transfer film may include a cover film.

The number of fisheyes with a diameter of 80 μm or more in the cover film is preferably 5 pieces/m2 or less and more preferably 0 pieces/m2. The “fisheye” refers to a defect that is generated when a foreign substance, an undissolved substance, an oxidatively deteriorated substance, and/or the like of a material is incorporated into the cover film during production of the cover film by, for instance, hot-melting, kneading, extruding, biaxially stretching, and/or casting the material.

The number of particles with a diameter of 3 μm or more included in the cover film is preferably 30 particles/mm² or less, more preferably 10 particles/mm² or less, even more preferably 5 particles/mm² or less, and particularly preferably 0 particles/mm². This configuration can suppress generation of defects when unevenness resulting from the particles included in the cover film is transferred to the photosensitive layer.

The arithmetic average roughness Ra of a surface of the cover film is preferably 0.01 μm or more, more preferably 0.02 μm or more, and even more preferably 0.03 μm or more. When Ra is within the foregoing range, for example in cases where the transfer film has an elongated shape, the winding property in winding the transfer film is excellent. The upper limit value thereof is preferably less than 0.50 μm, more preferably 0.40 μm or less, and even more preferably 0.30 μm or less in order to suppress defects during transfer.

Examples of the cover film include a polyethylene terephthalate film, a polypropylene film, a polystyrene film, and a polycarbonate film.

Examples of the cover film include those described in paragraphs 0083 to 0087 and 0093 of JP2006-259138A, the contents of which are incorporated herein.

Examples of the cover film include ALPHAN (registered trademark) FG-201 (manufactured by Oji F-Tex Co., Ltd.), ALPHAN (registered trademark) E-201F (manufactured by Oji F-Tex Co., Ltd.), Cerapeel (registered trademark) 25WZ (manufactured by TORAY ADVANCED FILM CO., LTD.), and LUMIRROR (registered trademark) 16QS62 (16KS40) (manufactured by Toray Industries, Inc.).

The cover film may be a recycled product. The recycled product is for example obtained by cleaning a used film or the like, forming it into a chip, and then forming the obtained material into a film. Exemplary commercial products of the recycled product include Ecouse series (manufactured by Toray Industries, Inc.).

### [Other Layers]

The transfer film may include other layers than the foregoing layers.

Such other layers include a high refractive index layer. Examples of the high refractive index layer include those described in paragraphs 0168 to 0188 of WO2021/187549, the contents of which are incorporated herein.

### [Transfer Film Production Method]

A transfer film production method is not particularly limited as long as it is a production method using the photosensitive composition.

In the transfer film production method, it is preferable to form the photosensitive layer by applying the photosensitive composition onto the temporary support.

Examples of a method of producing the transfer film 100 shown in the FIGURE include a production method involving a step of forming the photosensitive layer 14 by applying the photosensitive composition onto a surface of the temporary support 12 to form a coating film, followed by drying.

Further, the cover film is pressure-bonded to the photosensitive layer of the transfer film produced by the above production method, thus producing the transfer film 100 shown in the FIGURE. After being produced, the transfer film 100 shown in the FIGURE may also be wound up and stored in the form of a roll. The transfer film 100 in the form of a roll may be used, with the roll form being maintained, in a bonding step with respect to a substrate by a roll-to-roll method which will be described later.

The transfer film may include an interlayer and/or a thermoplastic resin layer.

Examples of a composition for forming an interlayer, an interlayer forming method, a composition for forming a thermoplastic resin layer, and a thermoplastic resin layer forming method include those described in paragraphs 0133 to 0136 and 0143 to 0144 of WO2021/033451, the contents of which are incorporated herein.

### [Photosensitive Layer Forming Method]

For a photosensitive layer forming method, known methods may be adopted for example.

One specific example is a forming method in which the above-described photosensitive composition is applied and dried.

Exemplary application methods include slit coating, spin coating, curtain coating, and inkjet coating.

The photosensitive composition used in the photosensitive layer forming method preferably contains a solvent. The solvent is as defined for the solvent that may be contained in the above-described photosensitive composition, and its preferable embodiment is also the same.

### Application

A pattern (cured film) obtained from the photosensitive layer formed using the above-described photosensitive composition or the above-described transfer film is applicable to various applications. For instance, it is applicable to an electrode protective film, an insulating film, a planarization film, an overcoat film, a hard coat film, a passivation film, a partition wall, a spacer, a microlens, an optical filter, an antireflection film, an etching resist, and a plating member.

More specific examples thereof include a protective film or an insulating film for a touch panel electrode, a protective film or an insulating film for a printed circuit board, a protective film or an insulating film for a TFT substrate, an interlayer insulating film in a build-up substrate of a semiconductor package, an organic interposer, a color filter, an overcoat film for a color filter, and an etching resist for wiring formation.

### [Laminate Production Method]

A laminate production method is not particularly limited as long as it is a method using the above-described photosensitive composition or the above-described transfer film.

The laminate production method preferably includes a step X1 to a step X3.

It is also preferable for the laminate production method to optionally further include a step X4 and/or a step 5 in addition to the steps X1 to X3.
Step X1: a step of forming a photosensitive layer on a substrate by using the photosensitive composition or the transfer film
Step X2: a step of subjecting the photosensitive layer to pattern exposure
Step X3: a step of forming a pattern by developing the exposed photosensitive layer with a developer
Step X4: a step of subjecting the pattern obtained by the development of the step 3 to exposure (preferably, full-surface exposure)
Step X5: a step of heating the pattern obtained through the steps X1 to X3 or the pattern obtained through the steps X1 to X4

The developer used in the step 3 may be an alkaline developer or an organic solvent developer.

When the specific siloxane polymer in the photosensitive layer includes a polymerizable group, and/or when the photosensitive layer contains a polymerizable compound, the developer used in the step 3 is preferably an alkaline developer.

The step 2 is preferably a step of reducing carboxy groups included in the specific siloxane polymer to change the solubility with respect to the developer, as described later. Particularly when the compound β is the compound β having the structure capable of accepting an electron from a carboxy group included in the specific siloxane polymer in a photoexcited state, in the step 2, radicals are generated in the system due to decarboxylation reaction of the specific siloxane polymer, and owing to the radicals, polymerization reaction of various compounds such as the specific siloxane polymer having a polymerizable group and the polymerizable compound can proceed. As a result of this, a negative pattern can be formed by using an alkaline developer as the developer in the step 3. The resulting pattern has a reduced content of carboxy groups and has a low relative permittivity.

When the specific siloxane polymer in the photosensitive layer is free of a polymerizable group and the photosensitive layer is free of a polymerizable compound, the developer used in the step 3 may be an alkaline developer or an organic solvent developer; however, when the developer used in the step 3 is an organic solvent developer, the step X3 is preferably followed by the step X4. In this case, when the developer used in the step 3 is an alkaline developer, a negative pattern can be formed, and when the developer used in the step 3 is an organic solvent developer, a positive pattern can be formed through the step 4. The resulting pattern has a reduced content of carboxy groups and has a low relative permittivity.

In addition, the step 5 can reduce the concentration of impurities in a pattern, and also the film strength may further improve since crosslinking reaction of unreacted residue of a silyl-containing component is promoted.

Each of the steps in the laminate production method is described in detail below.

### [Step X1]

The step X1 is a step of forming a photosensitive layer on a substrate.

In other words, the step X1 may be a step of forming a photosensitive layer using the photosensitive composition or a step of forming a photosensitive layer using the transfer film. In particular, the step X1 is preferably a step of forming a photosensitive layer using the photosensitive composition.

The photosensitive composition or the transfer film used in the step X1 is as described above.

When the photosensitive composition is used, the step X1 is preferably a step of forming a photosensitive layer by applying the photosensitive composition onto a substrate.

Examples of a method of applying the photosensitive composition include the photosensitive layer forming method in the transfer film production method described above.

When the transfer film is used, the step X1 is preferably a step of bringing the surface of the photosensitive layer on the side opposite to the temporary support side in the transfer film into contact with a substrate to bond the transfer film to the substrate.

In bonding, a known laminator may be used such as a laminator, a vacuum laminator, or an auto-cut laminator.

Examples of a bonding method include a known transfer method and a known laminating method, and a method in which the substrate is laid over the surface of the photosensitive layer and then pressurized and heated with a roll or the like is preferred.

Exemplary laminating methods include methods using known laminators such as a vacuum laminator and an auto-cut laminator.

A laminating temperature is preferably 70° C. to 130° C.

The step X1 is preferably carried out by a roll-to-roll method.

The substrate with which the transfer film is bonded is preferably a resin film or a resin film having a conductive layer.

The roll-to-roll method refers to a method in which a substrate that can be wound up and unwound is used as the substrate, a process of unwinding the substrate before one of steps included in the laminate production method and a process of winding the substrate after one of the steps are included, and at least one of the steps (preferably, all steps or all steps other than a heating step) is performed while the substrate is transported.

For an unwinding method and a winding method, known methods may be used.

### <Substrate>

Examples of the substrate include a glass substrate, a glass epoxy substrate, a silicon substrate, a resin substrate, and a substrate having a conductive layer.

The refractive index of the substrate is preferably 1.50 to 1.52.

The substrate may be constituted of a translucent substrate such as a glass substrate. For instance, tempered glass such as Gorilla glass (manufactured by Corning Incorporated) can also be used. Examples of materials contained in the substrate also include materials used in JP2010-086684A, JP2010-152809A, and JP2010-257492A.

The resin substrate is preferably a resin film having a small optical distortion and/or a high transparency. Examples of the resin substrate include polyethylene terephthalate (PET), polyethylene naphthalate, polycarbonate, triacetyl cellulose, a cycloolefin polymer, and polyimide.

The substrate having a conductive layer is preferably a resin substrate having a conductive layer and more preferably a resin film having a conductive layer because the production by a roll-to-roll method is possible.

As the substrate having a conductive layer, an organic substrate having a copper pattern is also favorable. Examples of the organic substrate include a resin substrate.

Examples of the conductive layer include a conductive layer used for circuit wiring or touch panel wiring.

The conductive layer is preferably at least one selected from the group consisting of a metal layer (e.g., a metal foil), a conductive metal oxide layer, a graphene layer, a carbon nanotube layer, and a conductive polymer layer, more preferably a metal layer, and even more preferably a copper layer or a silver layer, in terms of conductivity and fine line formability.

The conductive layer in the substrate having a conductive layer may be formed of one layer or two or more layers.

When the substrate having a conductive layer includes two or more conductive layers, those conductive layers may be the same or different and are preferably different.

Examples of a material of the conductive layer include a simple substance of metal and a conductive metal oxide.

Examples of the simple substance of metal include Al, Zn, Cu, Fe, Ni, Cr, Mo, Ag, and Au.

Examples of the conductive metal oxide include indium tin oxide (ITO), indium zinc oxide (IZO), and SiO₂. The term “conductive” means that the volume resistivity is less than 1×10⁶ Ω·cm, and the volume resistivity is preferably less than 1×10⁴ Ω·cm.

When the number of conductive layers in the substrate having a conductive layer is 2 or more, it is preferable that at least one of the conductive layers include the conductive metal oxide.

### [Step X2]

The step X2 is a step of subjecting the photosensitive layer to pattern exposure after the step X1 described above.

The step X2 is preferably a step of reducing the carboxy group content of the specific siloxane polymer in the photosensitive layer to change the solubility with respect to the developer.

The “pattern exposure” refers to exposure in a patterned manner, that is, exposure with an exposed portion and an unexposed portion being present. The positional relation between the exposed portion and the unexposed portion in the pattern exposure is not particularly limited.

As to the exposure direction, the exposure may be performed from the side of the photosensitive layer opposite to the substrate side or from the substrate side of the photosensitive layer.

The reduction rate of the carboxy group content of the specific siloxane polymer in the photosensitive layer can be obtained as follows: an infrared (IR) spectrum of the photosensitive layer before the exposure and that after the exposure are measured, and the reduction rate of the carboxy group content is calculated from a decrease in the height of a peak top of maximum absorption peak present in a wavelength range of 1680 to 1720 cm⁻¹. The maximum absorption peak of C═O stretching of a carboxy group appears, for instance, in a wavelength range of 1680 to 1720 cm⁻¹.

An exposure light source is not particularly limited as long as it is a light source emitting light in a wavelength range that allows for reduction of the carboxy group content of the specific siloxane polymer (light with a wavelength that allows for excitation of a specific structure in the compound α; for example, light with wavelengths of 254 nm, 313 nm, 365 nm, and 405 nm). Specific examples thereof include a super high pressure mercury lamp, a high pressure mercury lamp, a metal halide lamp, and a light emitting diode (LED).

The amount of exposure is preferably 10 to 10000 mJ/cm² and more preferably 50 to 3000 mJ/cm².

When the photosensitive layer is formed using the transfer film having the temporary support, the step X2 may be a step of performing the pattern exposure after the temporary support is peeled off from the photosensitive layer or a step of performing the pattern exposure through the temporary support before the temporary support is peeled off. The step 2 is preferably a step of performing the pattern exposure through the temporary support before the temporary support is peeled off because this can prevent photomask contamination caused by contact between the photosensitive layer and a photomask and prevent a negative influence of foreign substances adhering to the photomask on the exposure. Preferably, the temporary support is peeled off from the photosensitive layer before the step X3.

The pattern exposure may be exposure through a photomask or direct exposure using a laser or the like.

Examples of the photomask include a quartz mask, a soda-lime glass mask, and a film mask. A quartz mask is preferable because of excellent dimensional accuracy, and a film mask is preferable because an increase in size is easy.

For a material of the film mask, a polyester film is preferable, and a polyethylene terephthalate film is more preferable. One specific example is XPR-7S SG (manufactured by Fujifilm Global Graphic Systems).

### [Step X3]

The step X3 is a step of forming a pattern by developing the exposed photosensitive layer with a developer after the step X2 described above.

In the photosensitive layer exposed in the step X2, a difference in solubility with respect to the developer (solubility contrast) occurs between an exposed portion and an unexposed portion due to a reduction in the carboxy group content of the photosensitive layer in the exposed portion. Since the solubility contrast occurs in the photosensitive layer, a pattern can be formed in the step X3. For instance, when the developer in the step X3 is an alkaline developer, an unexposed portion is removed to form a negative pattern through the step X3. Meanwhile, when the developer in the step X3 is an organic solvent developer, an exposed portion is removed to form a positive pattern through the step X3. For the obtained positive pattern, it is preferable to reduce the carboxy group content of the specific siloxane polymer through the step X4 to be described later.

Examples of the developer include an alkaline developer and an organic solvent developer, with an alkaline developer being preferred.

The alkaline developer is not particularly limited as long as it is a developer capable of removing an unexposed portion of the photosensitive layer.

The alkaline developer is preferably an alkaline aqueous solution containing a compound having a pka of 7 to 13 at a concentration of 0.05 to 5 mol/L.

The alkaline developer may contain a water-soluble organic solvent and/or a surfactant.

The water content of the alkaline developer is preferably 50 mass % or more, more preferably 60 mass % or more, even more preferably 85 mass % or more, particularly preferably 90 mass % or more, and most preferably 95 mass % or more with respect to the total mass of the alkaline developer. The upper limit value thereof is preferably less than 100 mass %.

Examples of the alkaline developer include a sodium carbonate aqueous solution, a potassium carbonate aqueous solution, a sodium hydroxide aqueous solution, a potassium hydroxide aqueous solution, and a tetramethylammonium hydroxide aqueous solution. Examples of the concentration of an alkaline component forming the alkaline developer include a 0.1 mass % aqueous solution, a 1.0 mass % aqueous solution, and a 2.38 mass aqueous solution.

Examples of the alkaline developer also include those described in JP5-072724A and paragraph 0194 of WO2015/093271.

Examples of the organic solvent developer include developers containing organic solvents such as a ketone-based solvent, an ester-based solvent, an alcohol-based solvent, an amide-based solvent, an ether-based solvent, and a hydrocarbon-based solvent.

Examples of the organic solvent developer include cyclopentanone and propylene glycol monomethyl ether acetate.

The organic solvent developer may contain two or more organic solvents and may contain water.

The water content of the organic solvent developer is preferably less than 10 mass % with respect to the total mass of the organic solvent developer. More preferably, the organic solvent developer is substantially free of water. The organic solvent content of the organic solvent developer is preferably 50 mass % or more, more preferably 60 mass % or more, even more preferably 85 mass % or more, particularly preferably 90 mass % or more, and most preferably 95 mass % or more with respect to the total mass of the organic solvent developer. The upper limit value thereof is preferably 100 mass % or less.

Examples of a development method include puddle development, shower development, spin development, and dip development, and a development method in which the developer is sprayed onto the exposed photosensitive layer with a shower is preferable. After the development, a development residue may be removed by spraying a washing agent or the like with a shower while rubbing with a brush or the like. The liquid temperature of the developer is preferably 20° C. to 40° C.

[Step x4]

The step X4 is a step of exposing the pattern obtained in the step X3.

When the developer in the step X3 is an organic solvent developer, it is preferable to perform the step X4. The step X4 is a step of reducing the carboxy group content of the specific siloxane polymer by exposing the positive pattern obtained in the step 3.

Specifically, it is preferable to subject the photosensitive layer to pattern exposure by use of light with a wavelength that allows for excitation of a specific structure in the compound β in the photosensitive layer.

The exposure may be full-surface exposure or pattern exposure.

For an exposure method and exposure conditions, those in the step X2 may be adopted.

### [Step X5]

The step X5 is a step of heating the pattern obtained in the step X3 or the step X4.

The step X5 can reduce the concentration of impurities in the pattern, and also the film strength may further improve since crosslinking reaction of unreacted residue of a silyl-containing component is promoted.

The purity of the pattern means that components contained in the pattern are composed substantially only of the specific siloxane polymer. Specifically, the total content of the specific siloxane polymer is preferably 90 mass % or more and more preferably 95 mass % or more with respect to the total mass of the pattern. The upper limit value thereof is preferably 100 mass % or less with respect to the total mass of the pattern.

For instance, when the photosensitive composition and the photosensitive layer contain a polymerizable compound, the pattern obtained through the step 3 or the step 4 may contain polymeric impurities such as a polymer formed by polymerization of polymerizable compounds. It is assumed that when the step X5 is performed, such polymeric impurities are depolymerized and removed, whereby the purity of the pattern may improve.

The temperature of the heating treatment is preferably 150° C. to 400° C., more preferably 200° C. to 350° C., even more preferably 200° C. to 300° C., and particularly preferably 200° C. to 250° C.

The time of the heating treatment is preferably 1 to 24 hours, more preferably 1 to 12 hours, and even more preferably 1 to 9 hours.

The heating treatment may be performed in an air environment or in a nitrogen replacement environment.

The atmospheric pressure under the heating treatment environment is preferably 8.1 kPa or more, and more preferably 50.66 kPa or more. The upper limit value thereof is preferably 121.6 kPa or less, more preferably 111.46 kPa or less, and even more preferably 101.3 kPa or less.

### [Other Steps]

The laminate production method may include other steps in addition to the above-described steps.

Examples of the other steps include the following steps.

### <Step of Peeling Off Cover Film>

When the photosensitive layer is formed using the transfer film having a cover film, it is preferable that the laminate production method include a step of peeling off the cover film.

As a method of peeling off the cover film, for example, a known method can be adopted.

### <Step of Reducing Visible Light Reflectivity>

When the substrate is a substrate having a conductive layer, the laminate production method may include a step of performing a treatment of reducing the visible light reflectivity of the conductive layer.

When the substrate is a substrate having a plurality of conductive layers, the treatment of reducing the visible light reflectivity may be performed on some of the conductive layers or all of the conductive layers.

Examples of the treatment of reducing the visible light reflectivity include an oxidation treatment. One specific example is a treatment in which copper is oxidized and blackened as copper oxide, thereby reducing the visible light reflectivity of the conductive layer.

Examples of a suitable embodiment of the treatment of reducing the visible light reflectivity include the descriptions in paragraphs 0017 to 0025 of JP2014-150118A, and paragraphs 0041, 0042, 0048, and 0058 of JP2013-206315A, the contents of which are incorporated in the present specification.

### <Step of Etching>

When the substrate is a substrate having a conductive layer, the laminate production method may include a step of etching the conductive layer in a region where an etching resist film is not disposed, by use of the pattern formed through the step X3 or the step X4 as the etching resist film (etching step).

Examples of a method of the etching include a method by wet etching, which is described in paragraphs 0048 to 0054 of JP2010-152155A, and a method by dry etching such as known plasma etching.

It is also preferable for the laminate production method to use a substrate having a plurality of conductive layers on both surfaces and sequentially or simultaneously form patterns on the conductive layers formed on both surfaces.

With such a configuration, it is possible to form a first conductive pattern on one surface of the substrate and a second conductive pattern on the other surface. It is also preferable to form the patterns from both sides of the substrate by roll-to-roll.

### [Laminate]

The laminate is not particularly limited as long as it is a laminate produced by the laminate production method.

### [Circuit Wiring Production Method]

A circuit wiring production method is not particularly limited as long as it is a method of producing circuit wiring by use of the photosensitive composition or the transfer film.

The circuit wiring production method preferably includes: a step of bonding the transfer film and the substrate having a conductive layer together by bringing the surface of the photosensitive layer in the transfer film on the side opposite to the temporary support side into contact with a conductive layer of the substrate having a conductive layer or a step of forming the photosensitive layer by applying the photosensitive composition onto the substrate; a step of subjecting the photosensitive layer to pattern exposure; a step of developing the exposed photosensitive layer with a developer to form a pattern; a step of heating the pattern; and a step of etching the conductive layer in a region where the pattern is not disposed.

Examples of each step in the circuit wiring production method include each step in the laminate production method.

In the circuit wiring production method, it is preferable to repeat a set of steps plural times, where steps from the step of bonding or the step of forming the photosensitive layer using the photosensitive composition to the step of etching are defined as one set.

A film used as an etching resist film can also be used as a protective film (insulating film) for the formed circuit wiring.

### [Semiconductor Package Production Method]

Examples of a semiconductor package production method include a known production method such as a method of producing a build-up substrate.

Specific examples thereof include a semiconductor package production method including a step Z1, a step Z2, a step Z3, and a step Z4 (preferably a step Z1, a step Z2, a step 23, a step Z3-1, and a step Z4 in this order).
Step Z1: a step of forming a photosensitive layer on a substrate having a conductive layer by using the photosensitive composition or the transfer film
Step Z2: a step of subjecting the photosensitive layer to pattern exposure
Step Z3: a step of forming a pattern having a via by developing the exposed photosensitive layer with a developer
Step Z4: a step of forming a circuit pattern on the pattern
Step Z3-1: a step of heating the pattern

The step Z1, the step Z2, and the step Z3-1 in the semiconductor package production method are exemplified by the step X1, the step X2, and the step X5, respectively.

### [Step Z3]

The step Z3 is a step of forming a pattern having a via by developing the exposed photosensitive layer with a developer.

Examples of a method of development with a developer include the method of development with a developer in the step X3.

Examples of the shape of the via in the pattern include cross-sectional shapes of quadrangle, trapezoid, and inverted trapezoid; and front shapes (the shape of the via when observed from a direction in which the via bottom is visible) of circle and quadrangle.

For the shape of the via included in the pattern, an inverted trapezoid in cross section is preferable because this leads to an improved attachment property of plated copper to a via wall surface.

The size (diameter) of the via is usually 300 μm or less, preferably 200 μm or less, more preferably less than 40 μm, still more preferably 30 μm or less, even more preferably 20 μm or less, particularly preferably 15 μm or less, and most preferably 10 μm or less. The lower limit value thereof is preferably 1 μm or more and more preferably 5 μm or more.

The number of the vias may be 1 or 2 or more and is preferably 2 or more.

### [Step Z4]

The step Z4 is a step of forming a circuit pattern on the pattern.

For a method of forming the circuit pattern, a semi-additive process is preferable because this can form fine wiring.

In the semi-additive process, first, a seed layer is formed by performing an electroless copper plating treatment on the entire surfaces of the via bottom, the via wall surface, and the pattern after the step Z3 described above by use of a palladium catalyst or the like. The seed layer is used to form a power feeding layer for performing electrolytic copper plating.

The thickness of the seed layer is preferably 0.1 to 2.0 μm. When the thickness of the seed layer is 0.1 μm or more, the deterioration in connection reliability during electroless copper plating can be suppressed, and when the thickness of the seed layer is 2.0 μm or less, it is not necessary to increase the etching amount in flash-etching the seed layer between wiring lines, and the damage to the wiring lines during etching can also be suppressed.

The electroless copper plating treatment is performed through deposition of metallic copper on the surface of the pattern having a via by reaction between copper ions and a reducing agent.

Examples of an electroless plating treatment method and an electrolytic plating treatment method include known plating treatment methods.

For a catalyst used in the electroless plating treatment process, a palladium-tin mixed catalyst is preferable. The average particle size of the mixed catalyst is preferably 10 nm or less. A plating composition used in the electroless plating treatment process preferably contains hypophosphorous acid as a reducing agent.

Exemplary commercial products of an electroless copper plating solution include “MSK-DK” manufactured by Atotech Japan K.K. and “SULKACUP (registered trademark) PEA ver. 4” series manufactured by Uemura Kogyo Co., Ltd.

It is preferable that, after the electroless copper plating treatment, the surface of the photosensitive layer in the transfer film on the side opposite to the temporary support be thermocompression-bonded to the electroless copper plating by a roll laminator.

The thickness of the photosensitive layer is preferably 5 to 30 μm because the height of the photosensitive layer can be larger than that of the wiring after electrolytic copper plating.

It is preferable that, after the thermalcompression bonding of the transfer film, the photosensitive layer is exposed through a photomask on which a desired wiring pattern is drawn. For an exposure method, that in the step X2 may be adopted.

Further, the temporary support of the transfer film is peeled off after the exposure, and the exposed photosensitive layer is developed with an alkaline developer to form a pattern. In addition, after the pattern is formed, a development residue of the photosensitive composition may be removed using plasma or the like.

After the development, formation of a copper circuit layer and via filling may be carried out by electrolytic copper plating.

After the electrolytic copper plating, the pattern may be peeled off using an alkaline aqueous solution or an amine-based peeling agent, and the seed layer between wiring lines may be removed (flash etching). The flash etching is performed using, for example, an oxidizing solution containing sulfuric acid and an acidic solution such as hydrogen peroxide. Examples of the oxidizing solution include “SAC” manufactured by JCU Corporation and “CPE-800” manufactured by Mitsubishi Gas Chemical Company, Inc. After the flash etching, palladium or the like adhering to a part between wiring lines is removed as necessary. Palladium may be removed using an acidic solution such as nitric acid or hydrochloric acid.

It is preferable to perform a post-baking treatment after the peeling of the pattern or after the flash etching. The post-baking treatment sufficiently thermally cures an unreacted thermosetting component, and this improves the electrical insulation reliability, the curing characteristics, and the adhesive strength with respect to the plated copper.

The curing temperature is preferably 150° C. to 240° C. The curing time is preferably 15 to 500 minutes.

The semiconductor package production method may include a roughening step of roughening the pattern having a via. The roughening step is preferably performed between the step Z3-1 and the step Z4.

When the roughening step is performed, the pattern surface can be roughened to thereby improve the adhesion with respect to the circuit wiring, while removing smears.

Examples of the roughening step include a known desmearing treatment, and a treatment of bringing a roughening liquid into contact is preferable.

Examples of the roughening liquid include a roughening liquid containing chromium and sulfuric acid, a roughening liquid containing an alkali permanganate (e.g., a sodium permanganate roughening liquid), and a roughening liquid containing sodium fluoride, chromium, and sulfuric acid.

The step Z1, the step 22, the step Z3, and the step Z4 (preferably, the step Z1, the step Z2, the step Z3, the step Z3-1, and the step 24) may be repeated according to the required number of layers. It is also preferable to form a solder resist on the outermost layer of the resulting semiconductor package.

### [Semiconductor Device Production Method]

A semiconductor device production method is not particularly limited as long as it is a production method including the semiconductor package production method.

Exemplary semiconductor devices include semiconductor devices such as a semiconductor package used in electrical products (e.g., a computer, a mobile phone, a digital camera, and a television) and vehicles (e.g., a motorcycle, an automobile, a train, a ship, and an airplane).

### [Semiconductor Package]

A semiconductor package is not particularly limited as long as it includes the above-described laminate.

A pattern (cured film) may be used as an insulating film or an organic interposer in a build-up substrate.

### EXAMPLES

Hereinafter, the embodiment of the present invention is described in more detail with reference to Examples. The materials, amounts of use, ratios, treatments, and treatment procedures illustrated in the examples below may be modified as appropriate as long as they do not depart from the scope and spirit of the present invention. Accordingly, the scope of the present invention should not be construed as being limited to the following examples.

In Examples, unless otherwise specified, “part” and “g” mean “part by mass” and “mass %”, respectively.

### [Preparation of Photosensitive Composition]

Various components were mixed at the solid content ratio as shown in tables below, and the mixture was diluted such that the solid concentration was 30 mass %, the methyl ethyl ketone (MEK) concentration was 20 mass %, and the N-methylpyrrolidone (NMP) concentration was 50 mass %, thus preparing a photosensitive composition. When silica was not a slurry (i.e., when silica was powder), the silica was dispersed in a 50 mass % MEK solution to be a slurry and then finally mixed with other components to prepare a photosensitive composition.

### [Siloxane Polymer]

Siloxane polymers (Aa-1) to (Aa-6) in Table 2 are shown below. Synthetic products were used as the siloxane polymers (Aa-1) to (Aa-6).

### Synthesis of Siloxane Polymer (Aa-1)

### Synthesis of Monomer M

To 500 g of ethyl acetate, 50 g of succinic anhydride was dissolved, and then 90 g of aminopropyltrimethoxysilane was slowly added to the obtained solution. The solution was stirred at room temperature for 2 hours and, after the disappearance of the raw materials was confirmed, concentrated to thereby obtain a monomer M.

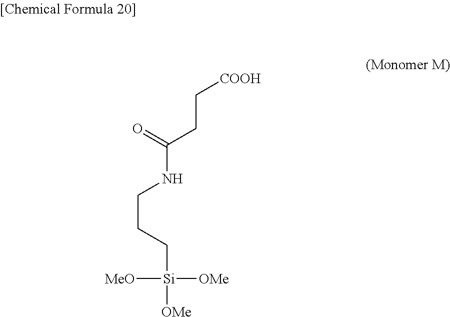 [SMILES: CO[Si](CCCNC(=O)CCC(=O)O)(OC)OC]

### Synthesis of Siloxane Polymer (Aa-1)

The monomer M (14.0 g), phenyltrimethoxysilane (9.9 g), ethyl acetate (50 g), and isopropanol (25 g) were mixed. To the mixture, 0.2 g of concentrated hydrochloric acid and 5.6 g of water were added and reacted at 50° C. for 5 hours. To the resulting reaction liquid, 100 g of 1-methoxy-2-propanol was added and concentrated to 30 g, and this operation was conducted two times, whereby hydrochloric acid, water, ethyl acetate, and isopropanol were removed, and a 1-methoxy-2-propanol solution of siloxane polymer (Aa-1) was obtained.

The weight-average molecular weight of the obtained polymer on a standard polystyrene basis, as measured by a GPC method, was 3,000, and the acid value was 120 mgKOH/g.

### Synthesis of Siloxane Polymers (Aa-2) to (Aa-6)

Siloxane polymers (Aa-2) to (Aa-6) were synthesized in the same manner as that for the siloxane polymer (Aa-1) except that the type and the amount of a monomer blended were changed.

### Synthesis of Siloxane Polymers (Aa-1) to (Aa-6)

The siloxane polymers (Aa-1) to (Aa-6) are shown below. The compositional ratio of a repeating unit of each polymer is a value in molar percentage.

Table 1 shows the weight-average molecular weights, acid values (mgKOH/g), and double bond values (C═C values (mmol/g)) of the siloxane polymers (Aa-1) to (Aa-6). The double bond value is a value measured by a titration method using iodine.

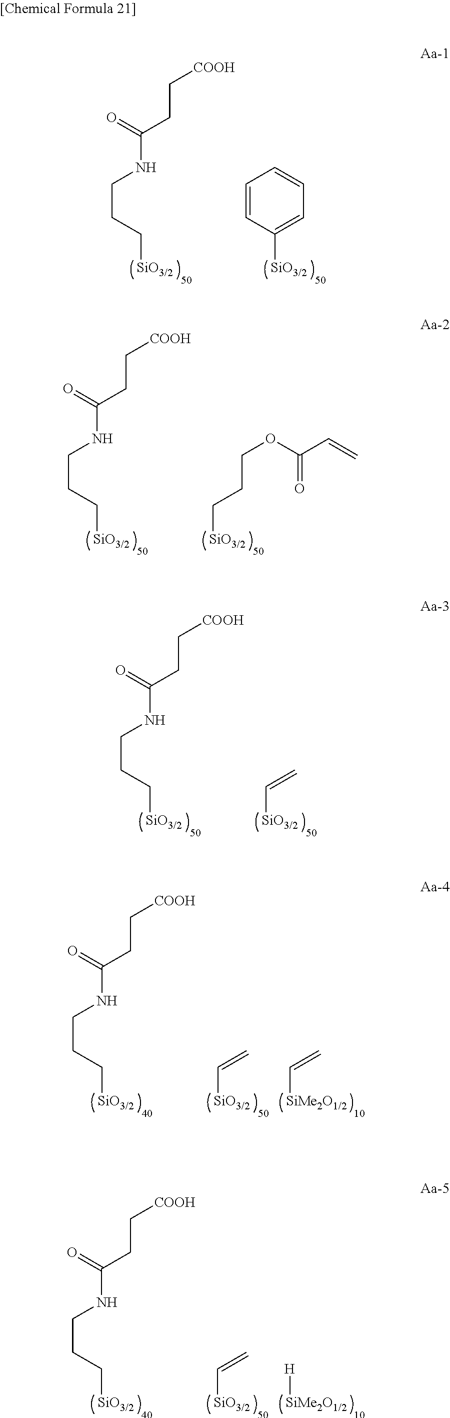

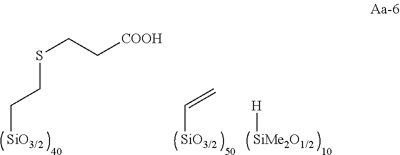

TABLE 1

| Siloxane | Weight-average | Acid value | C═C value |
|---|---|---|---|
| polymer | molecular weight | (mgKOH/g) | (mmol/g) |
| Aa-1 | 3000 | 120 | 0 |
| Aa-2 | 5200 | 94 | 3.9 |
| Aa-3 | 4600 | 142 | 5.9 |
| Aa-4 | 2800 | 179 | 4.2 |
| Aa-5 | 3200 | 171 | 3.8 |
| Aa-6 | 13000 | 152 | 5.4 |

### [Compound β]

2,4-DMQ: 2,4-dimethylquinoline
1-MIQ: 1-methylisoquinoline
9MeAC: 9-methylacridine

### [Filler]

YA050C-MJE: spherical silica slurry, methacrylic surface-treated product, MEK slurry with solid concentration of 50 mass %, manufactured by Admatechs Co., Ltd.
SFP-20M: silica, manufactured by Denka Company Limited
SO-C2: silica, manufactured by Admatechs Co., Ltd.

### [Polymerizable Compound]

NK4G: NK Ester 4G (bifunctional polyethylene glycol methacrylate), manufactured by SHIN-NAKAMURA CHEMICAL Co., Ltd.
A-NOD-N: NK Ester A-NOD-N (bifunctional alkyl acrylate), manufactured by SHIN-NAKAMURA CHEMICAL Co., Ltd.
DPHA: dipentaerythritol hexaacrylate, manufactured by Tokyo Chemical Industry Co., Ltd.

### [Photopolymerization Initiator]

Oxe01: IRGACURE OXE-01, manufactured by BASF
Omn-379EG: Omnirad 379EG, manufactured by IGM Resins B.V.

### [Measurement of Average Particle Size]

The photosensitive composition of each of Examples and Comparative Examples was applied onto a glass substrate and dried to form a coating film with a thickness of 4.0 μm.

A cross section extending along the normal direction to the surface of the obtained coating film was cut out and observed with a scanning electron microscope, and the major axes of all particles of a filler observed within a region whose length in the vertical direction parallel to the thickness direction of the coating film was 3 μm and whose length in the horizontal direction perpendicular to the vertical direction was 10 μm, were measured.

The operation above was carried out for five different places in the coating film, and the average (arithmetic mean) of the major axes of all particles of the filler in the five places as measured by the operation was determined as the average particle size of the filler.

It should be noted that, in the photosensitive composition of each of Examples and Comparative Examples, after the foregoing measurement of the average particle size, the coating film was heated at 230° C. for 8 hours and then the average particle size was again measured according to the same procedures as above; as a result, the obtained value was the same as the average particle size obtained before the heating treatment.

### Evaluation 1: Photolithography Properties (Resolution)

### Application Method

Each of the photosensitive compositions shown in Table 2 was applied on glass (Corning glass, 5 cm in length x 5 cm in width×1.1 mm in thickness) and dried such that the thickness after drying was 10 μm, thus forming a photosensitive layer.

A temporary support (PET film, LUMIRROR 16FB40, thickness: 16 μm, manufactured by Toray Industries, Inc.) and a photomask were laminated on the obtained photosensitive layer in this order to obtain a laminate.

As the photomask, use was made of a photomask having a plurality of circular light shielding portions with diameters of 20 μm, 15 μm, and 10 μm, where the distance between two light shielding portions (the distance from the center of one circle to the center of another circle) was 300 μm.

The obtained laminate was subjected to pattern exposure from the side of the photomask opposite to the temporary support side using a super high pressure mercury lamp. In this process, an integrated illuminance measured with a 365 nm-wavelength illuminance meter was 500 mJ/cm². Thereafter, the photomask was removed from the laminate.

After the exposure, the laminate was allowed to stand for 30 minutes, the temporary support was peeled off from the laminate, and the laminate was developed for 60 seconds using a 1 mass % aqueous solution of sodium carbonate (liquid temperature: 25° C.) as a developer. After the development, the laminate was rinsed with pure water as a rinsing liquid at room temperature for 20 seconds, and further, air was blown to remove the residual rinsing liquid. The resulting product was subjected to a heating treatment (250° C., 8 hours) in an oven, and the photolithography properties were evaluated based on the diameter of the smallest via (smallest resolution pattern size) among vias formed with no film reduction and no residue at the bottom of the vias.

### <Evaluation Criteria for Photolithography Properties (Resolution)>

A: A via with a diameter of 10 μm was formed.
B: A via with a diameter of 15 μm was formed.
C: A via with a diameter of 20 μm was formed.
D: The entire surface was dissolved by development and no via was formed.

### [Transfer Film Method]

Aside from that, each of the photosensitive compositions was applied on a temporary support (PET film, LUMIRROR 16FB40, thickness: 16 μm, manufactured by Toray Industries, Inc.) and dried to form a photosensitive layer with a film thickness of 10 μm.

Next, a cover film (polypropylene film, FG-201, thickness: 30 μm, manufactured by Oji F-Tex Co., Ltd.) was provided on the photosensitive layer to obtain a transfer film.

The cover film was peeled off from the transfer film thus produced, and the resulting film was laminated on a polyimide substrate having thereon a copper pattern with a line width of 3 μm, thereby obtaining a laminate having the lamination structure in the order of “temporary support/photosensitive layer/copper pattern/substrate (polyimide).” The conditions of the lamination were specified to a substrate temperature of 40° C., a rubber roller temperature (lamination temperature) of 100° C., a linear pressure of 3 N/cm, and a transportation speed of 1 m/min. Lamination properties were good.

Each transfer film was evaluated in the same manner as that for the application method described above, and the evaluation result of each transfer film for the photolithography properties was the same as that obtained in the application method.

### Evaluation 2: Evaluations of CTE, Relative Permittivity, Dielectric Loss Tangent

### [Production of Measurement Sample]

For each of the photosensitive compositions given in Table 2 provided below, a measurement sample was produced by the following method X.

A copper-clad polyimide film (METALOYAL, manufactured by Toray Industries, Inc.) was used as a substrate, and each photosensitive composition shown in Table 2 was applied onto the substrate and dried to obtain a laminate including a photosensitive layer with a thickness of 10.0 μm on the substrate. The obtained laminate was exposed (high pressure mercury lamp, integrated illuminance measured with a 365 nm-wavelength illuminance meter: 100 mJ/cm²) from the side of the photosensitive layer opposite to the substrate side, subjected to dip development with a 1 mass % aqueous solution of sodium carbonate (liquid temperature: 25° C.) for 90 seconds, subsequently rinsed with pure water as a rinsing liquid at room temperature for 20 seconds, and further blown with air to remove the residual rinsing liquid. This was subjected to a heating treatment (250° C., 8 hours) in an oven, subsequently immersed in a 2M hydrochloric acid for 8 hours for a peeling treatment, and rinsed (with pure water at normal temperature for 1 hour), and then the photosensitive layer was peeled off from the substrate to obtain a self-supporting film derived from the photosensitive layer. When the self-supporting film could not be peeled off in the above peeling treatment, the film was further immersed in a 2M hydrochloric acid for approximately 1 week and peeled off. The obtained self-supporting film was cut into strips to obtain measurement samples.

### [Coefficient of Thermal Expansion (CTE)]

Each measurement sample obtained by the method X was processed into 19 mm×5 mm, and the CTE was measured using a thermomechanical analyzer (TMA, TMA450EM manufactured by TA Instruments). The measurement conditions were specified to a temperature rising rate of 10° C./min, a distance between chucks of 16 mm, and a load of 49 mN. The measurement was performed in a temperature range of −60° C. to 350° C. The CTE was the average value (ppm/K) in a range of 50° C. to 100° C. during temperature rise. The measurement was performed on three samples, and the average value thereof was defined as the average value X (ppm/K).

### <Evaluation Criteria for CTE>

A: The average value X was less than 15 ppm/K.
B: The average value X was 15 ppm/K or more and less than 20 ppm/K.
C: The average value X was 20 ppm/K or more and less than 30 ppm/K.
D: The average value X was 30 ppm/K or more and less than 50 ppm/K.
E: The average value X was 50 ppm/K or more and less than 60 ppm/K.
F: The average value X was 60 ppm/K or more.

### [Relative Permittivity and Dielectric Loss Tangent]

For each measurement sample obtained by the method X, the relative permittivity and the dielectric loss tangent were measured using a 28 GHZ split cylinder-type resonator (manufactured by Kanto Electronics Application & Development Inc.).

The measurement was performed on three samples, and the relative permittivity and the dielectric loss tangent were evaluated based on the average value thereof.

### <Evaluation Criteria for Relative Permittivity>

A: The relative permittivity was less than 2.9.
B: The relative permittivity was 2.9 or more and less than 3.1.
C: The relative permittivity was 3.1 or more and less than 3.3.
D: The relative permittivity was 3.3 or more.

### <Evaluation Criteria for Dielectric Loss Tangent>

A: The dielectric loss tangent was less than 0.005.
B: The dielectric loss tangent was 0.005 or more and less than 0.007.
C: The dielectric loss tangent was 0.007 or more and less than 0.010.
D: The dielectric loss tangent was 0.010 or more and less than 0.015.
E: The dielectric loss tangent was 0.015 or more.

Table 2 is shown below.

The “Content” column shows the solid concentration (mass %) of the component with respect to the total solid content of the photosensitive composition.

The term “Measurement impossible” in the evaluation result space in Comparative Example 1 means that no pattern was able to be formed using the photosensitive composition of Comparative Example 1-1 (i.e., the entire surface was dissolved in the developing treatment), and none of the CTE, the average relative permittivity, and the average dielectric loss tangent was able to be measured accordingly.

TABLE 2

| | | | | | (C) Filler | | | | | |
|---|---|---|---|---|---|---|---|---|---|---|
| | (A) Siloxane | | | | | | Average | | (D) Polymerizable | |
| Table 2 | polymer | | (B) Compound β | | | | particle | | compound | |
| (1/2) | Type | Content | Type | Content | Type | Material | size | Content | Type | Content |
| EX 1-1 | Aa-1 | 95.0% | 2, 4-DMQ | 5.0% | | | | | | |
| EX 1-2 | Aa-2 | 95.0% | 2, 4-DMQ | 5.0% | | | | | | |
| EX 1-3 | Aa-3 | 95.0% | 2, 4-DMQ | 5.0% | | | | | | |
| EX 1-4 | Aa-4 | 95.0% | 2, 4-DMQ | 5.0% | | | | | | |
| EX 1-5 | Aa-5 | 95.0% | 2, 4-DMQ | 5.0% | | | | | | |
| EX 1-6 | Aa-6 | 95.0% | 2, 4-DMQ | 5.0% | | | | | | |
| EX 1-7 | Aa-5 | 97.0% | 2, 4-DMQ | 3.0% | | | | | | |
| EX 1-8 | Aa-5 | 92.0% | 2, 4-DMQ | 8.0% | | | | | | |
| EX 1-9 | Aa-5 | 95.0% | 1-MIQ | 5.0% | | | | | | |
| EX 1-10 | Aa-5 | 95.0% | 9MeAC | 5.0% | | | | | | |
| EX 1-11 | Aa-5 | 89.3% | 9MeAC | 5.0% | | | | | NK4G | 5.0% |
| EX 1-12 | Aa-5 | 84.3% | 9MeAC | 5.0% | | | | | NK4G | 10.0% |
| EX 1-13 | Aa-5 | 79.3% | 9MeAC | 5.0% | | | | | NK4G | 15.0% |
| CE 1-1 | Aa-1 | 100.0% | | | | | | | | |
| CE 1-2 | Aa-1 | 74.0% | | | | | | | NK4G | 25.0% |

| | (E) | | | | | |
|---|---|---|---|---|---|---|
| | Photopolymerization | | Evaluation | | | |
| Table 2 | initiator | | | | Relative | Dielectric |
| (1/2) | Type | Content | Resolution | CTE | permittivity | loss tangent |
| EX 1-1 | | | A | E | B | D |
| EX 1-2 | | | A | D | B | D |
| EX 1-3 | | | A | D | A | C |
| EX 1-4 | | | A | D | A | C |
| EX 1-5 | | | A | D | A | C |
| EX 1-6 | | | A | D | A | C |
| EX 1-7 | | | A | D | A | C |
| EX 1-8 | | | A | D | A | C |
| EX 1-9 | | | A | D | A | C |
| EX 1-10 | | | A | D | A | C |
| EX 1-11 | Oxe01 | 0.7% | A | D | A | C |
| EX 1-12 | Oxe01 | 0.7% | A | D | A | C |
| EX 1-13 | Oxe01 | 0.7% | A | E | B | D |
| CE 1-1 | | | D | Evaluation | Evaluation | Evaluation |
| | | | | impossible | impossible | impossible |
| CE 1-2 | Oxe01 | 1.0% | C | F | D | E |

EX: Example
CE: Comparative Example

TABLE 3

| | | | | | (C) Filler | | | | | |
|---|---|---|---|---|---|---|---|---|---|---|
| | (A) Siloxane | | | | | | Average | | (D) Polymerizable | |
| Table 2 | polymer | | (B) Compound β | | | | particle | | compound | |
| (2/2) | Type | Content | Type | Content | Type | Material | size | Content | Type | Content |
| EX 2-1 | Aa-1 | 23.0% | 9MeAC | 2.0% | YA050C-MJE | Silica | 50 nm | 75.0% | | |
| EX 2-2 | Aa-2 | 23.0% | 9MeAC | 2.0% | YA050C-MJE | Silica | 50 nm | 75.0% | | |
| EX 2-3 | Aa-3 | 23.0% | 9MeAC | 2.0% | YA050C-MJE | Silica | 50 nm | 75.0% | | |
| EX 2-4 | Aa-4 | 23.0% | 9MeAC | 2.0% | YA050C-MJE | Silica | 50 nm | 75.0% | | |
| EX 2-5 | Aa-5 | 23.0% | 9MeAC | 2.0% | YA050C-MJE | Silica | 50 nm | 75.0% | | |
| EX 2-6 | Aa-6 | 23.0% | 9MeAC | 2.0% | YA050C-MJE | Silica | 50 nm | 75.0% | | |
| EX 2-7 | Aa-5 | 23.0% | 9MeAC | 2.0% | SFP-20M | Silica | 300 nm | 75.0% | | |
| EX 2-8 | Aa-5 | 23.0% | 9MeAC | 2.0% | SO-C2 | Silica | 500 nm | 75.0% | | |
| EX 2-9 | Aa-5 | 28.0% | 9MeAC | 2.0% | YA050C-MJE | Silica | 50 nm | 70.0% | | |
| EX 2-10 | Aa-5 | 33.0% | 9MeAC | 2.0% | YA050C-MJE | Silica | 50 nm | 65.0% | | |
| EX 2-11 | Aa-5 | 38.0% | 9MeAC | 2.0% | YA050C-MJE | Silica | 50 nm | 60.0% | | |
| EX 2-12 | Aa-5 | 48.0% | 9MeAC | 2.0% | YA050C-MJE | Silica | 50 nm | 50.0% | | |
| EX 2-13 | Aa-5 | 68.0% | 9MeAC | 2.0% | YA050C-MJE | Silica | 50 nm | 30.0% | | |
| EX 2-14 | Aa-5 | 22.3% | 9MeAC | 2.0% | YA050C-MJE | Silica | 50 nm | 70.0% | NK4G | 5.0% |
| EX 2-15 | Aa-5 | 17.3% | 9MeAC | 2.0% | YA050C-MJE | Silica | 50 nm | 70.0% | NK4G | 10.0% |
| EX 2-16 | Aa-5 | 12.3% | 9MeAC | 2.0% | YA050C-MJE | Silica | 50 nm | 70.0% | NK4G | 15.0% |
| EX 2-17 | Aa-5 | 21.0% | 9MeAC | 2.0% | YA050C-MJE | Silica | 50 nm | 70.0% | NK4G | 5.0% |
| EX 2-18 | Aa-5 | 22.3% | 9MeAC | 2.0% | YA050C-MJE | Silica | 50 nm | 70.0% | A-NOD- | 5.0% |
| | | | | | | | | | N | |
| EX 2-19 | Aa-5 | 22.3% | 9MeAC | 2.0% | YA050C-MJE | Silica | 50 nm | 70.0% | DPHA | 5.0% |

| | (E) | | | | | |
|---|---|---|---|---|---|---|
| | Photopolymerization | | Evaluation | | | |
| Table 2 | initiator | | | | Relative | Dielectric |
| (2/2) | Type | Content | Resolution | CTE | permittivity | loss tangent |
| EX 2-1 | | | A | B | B | B |
| EX 2-2 | | | A | A | B | B |
| EX 2-3 | | | A | A | A | A |
| EX 2-4 | | | A | A | A | A |
| EX 2-5 | | | A | A | A | A |
| EX 2-6 | | | A | A | A | A |
| EX 2-7 | | | A | A | A | A |
| EX 2-8 | | | B | A | A | A |
| EX 2-9 | | | A | A | A | A |
| EX 2-10 | | | A | A | A | A |
| EX 2-11 | | | A | B | A | A |
| EX 2-12 | | | A | B | A | B |
| EX 2-13 | | | A | C | A | C |
| EX 2-14 | Oxe01 | 0.7% | A | A | A | A |
| EX 2-15 | Oxe01 | 0.7% | A | A | A | A |
| EX 2-16 | Oxe01 | 0.7% | A | B | B | B |
| EX 2-17 | Omn- | 2.0% | A | A | A | A |
| | 379EG | | | | | |
| EX 2-18 | Oxe01 | 0.7% | A | B | A | A |
| EX 2-19 | Oxe01 | 0.7% | A | C | A | B |

EX: Example

The evaluation results shown in Table 2 clearly reveal that the photosensitive composition according to the embodiment of the present invention exhibits desired effects.

The comparison between Examples 1-1 and 1-2 demonstrates that when the specific siloxane polymer contains a polymerizable group, the CTE of a formed pattern is smaller.

The comparison among Examples 1-1 to 1-5 demonstrates that when the specific siloxane polymer contains a repeating unit in which a group represented by —Y—(Z)p is bonded to a silicon atom of a siloxane bond, Y represents a single bond, Z represents a vinyl group, and p represents 1, at least one of the CTE, the relative permittivity, and the dielectric loss tangent of a formed pattern is smaller.

The comparison among Examples 1-11 to 1-13 and the comparison among Examples 2-14 to 1-16 demonstrate that when the photosensitive composition contains a polymerizable compound and when the polymerizable compound content is 10.0 mass % or less with respect to the total mass of the photosensitive composition, at least one of the CTE, the relative permittivity, and the dielectric loss tangent of a formed pattern is smaller.

The comparison among Examples demonstrates that when the photosensitive composition contains a filler, at least one of the CTE, the relative permittivity, and the dielectric loss tangent of a formed pattern is smaller.

The comparison between Examples 2-5, 2-7, and 2-8 demonstrates that when the average particle size of the filler is 300 nm or less, the resolution is more excellent.

The comparison among Examples 2-5 and 2-9 to 2-13 demonstrates that when the filler content is 50.0 mass % or more (preferably 60.0 mass % or more, and more preferably 70.0 mass or more) with respect to the total mass of the photosensitive composition, at least one of the CTE and the dielectric loss tangent of a formed pattern is smaller.

The comparison among Examples 2-17 to 2-19 demonstrates that when the photosensitive composition contains a polymerizable compound and at the same time when a polymerizable group in the polymerizable compound is a methacryloyl group, the CTE of a formed pattern is smaller. The reason of this is presumed as follows: when a polymerizable group in the polymerizable compound is a methacryloyl group, depolymerization reaction easily proceeds in the heating treatment (step Z5) of a pattern, and consequently the amount of impurities in the pattern is easily reduced. It was also confirmed that when the number of functional groups in the polymerizable compound is 4 or less (preferably 2), at least one of the CTE and the dielectric loss tangent of a formed pattern is smaller. The reason of this is presumed as follows: since the number of polymerizable groups in the polymerizable compound is small and the polymerizable group is an acryloyl group, depolymerization reaction easily proceeds in the heating treatment (step Z5) of a pattern, and consequently the amount of impurities is easily reduced.

In each Example, a measurement sample was produced by using a transfer film produced with the following procedures instead of forming a photosensitive layer using the photosensitive composition.

Each of the photosensitive compositions was applied on a temporary support (PET film, LUMIRROR 16FB40, thickness: 16 μm, manufactured by Toray Industries, Inc.) and dried to form a photosensitive layer with a film thickness of 10 μm.

Next, a cover film (polypropylene film, FG-201, thickness: 30 μm, manufactured by Oji F-Tex Co., Ltd.) was provided on the photosensitive layer to obtain a transfer film.

The cover film was peeled off from the obtained transfer film, and the photosensitive layer exposed outside was laminated on a copper surface of a copper-clad polyimide film (METALOYAL, manufactured by Toray Industries, Inc.). The conditions of the lamination were specified to a substrate temperature of 40° C., a rubber roller temperature (lamination temperature) of 100° C., a linear pressure of 3 N/cm, and a transportation speed of 1 m/min. Lamination properties were good. Further, the temporary support was peeled off from the obtained sample to obtain a laminate having the lamination structure in the order of “photosensitive layer/copper/substrate (polyimide).”

The obtained laminate was exposed (high pressure mercury lamp, integrated illuminance measured with a 365 nm-wavelength illuminance meter: 100 mJ/cm²) from the side of the photosensitive layer opposite to the substrate side, subjected to dip development with a 1 mass % aqueous solution of sodium carbonate (liquid temperature: 25° C.) for 90 seconds, subsequently rinsed with pure water as a rinsing liquid at room temperature for 20 seconds, and further blown with air to remove the residual rinsing liquid. This was subjected to a heating treatment (250° C., 8 hours) in an oven, subsequently immersed in a 2M hydrochloric acid for 8 hours for a peeling treatment, and rinsed (with pure water at normal temperature for 1 hour), and then the photosensitive layer was peeled off from the substrate to obtain a self-supporting film derived from the photosensitive layer. When the self-supporting film could not be peeled off in the above peeling treatment, the film was further immersed in a 2M hydrochloric acid for approximately 1 week and peeled off. The obtained self-supporting film was cut into strips to obtain measurement samples.

The obtained measurement samples were evaluated for the coefficient of thermal expansion (CTE), the average relative permittivity, and the average dielectric loss tangent in the same manner as that for the photosensitive composition, and the same evaluation results as those of the measurement samples produced by the method X above were obtained.

### REFERENCE SIGNS LIST

12: temporary support
14: photosensitive layer
16: cover film
100: transfer film

1. A photosensitive composition comprising:
a siloxane polymer having a carboxy group; and
a compound β having a structure that allows an amount of the carboxy group included in the siloxane polymer to reduce upon exposure.

2. The photosensitive composition according to claim 1,
wherein the siloxane polymer has a repeating unit represented by Formula (a1), 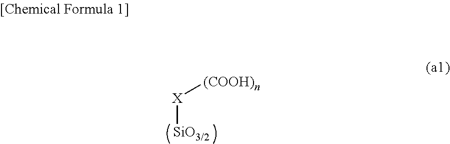
where X represents an (n+1) valent linking group, and n represents an integer of 1 or more.

3. The photosensitive composition according to claim 1,
wherein the siloxane polymer further has a polymerizable group.

4. The photosensitive composition according to claim 1,
wherein the compound β is a compound β having a structure capable of accepting an electron from the carboxy group included in the siloxane polymer in a photoexcited state.

5. The photosensitive composition according to claim 1,
wherein the compound β is a nitrogen-containing aromatic compound.

6. The photosensitive composition according to claim 1, further comprising a filler.

7. The photosensitive composition according to claim 6,
wherein a content of the filler is 50 mass % or more with respect to a total solid content of the photosensitive composition.

8. The photosensitive composition according to claim 6,
wherein an average particle size of the filler is 300 nm or less.

9. A photosensitive composition comprising:
a siloxane polymer having a carboxy group and a polymerizable group;
a compound β having a structure that allows an amount of the carboxy group included in the siloxane polymer to reduce upon exposure; and
a filler,
wherein the siloxane polymer has a repeating unit represented by Formula (a1),
the compound β is a nitrogen-containing aromatic compound, and
an average particle size of the filler is 300 nm or less, 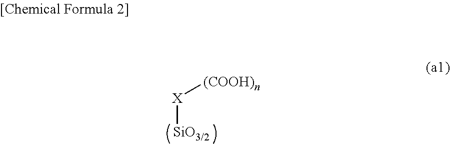
where X represents an (n+1) valent linking group, and n represents an integer of 1 or more.

10. The photosensitive composition according to claim 1, further comprising a polymerizable compound.

11. The photosensitive composition according to claim 1, further comprising a photopolymerization initiator.

12. A transfer film comprising:
a temporary support; and
a photosensitive layer formed of the photosensitive composition according to claim 1.

13. A laminate production method comprising:
a step X1 of forming a photosensitive layer on a substrate by using the photosensitive composition according to claim 1;
a step X2 of subjecting the photosensitive layer to pattern exposure; and
a step X3 of forming a pattern by developing the photosensitive layer exposed, with a developer.

14. The laminate production method according to claim 13,
wherein the step X2 is a step of reducing the amount of the carboxy group included in the siloxane polymer to change solubility with respect to a developer.

15. The laminate production method according to claim 13,
wherein the substrate is an organic substrate having a copper pattern.

16. The laminate production method according to claim 13,
wherein the developer is an alkaline developer.

17. A laminate produced by the laminate production method according to claim 13.

18. A semiconductor package comprising the laminate according to claim 17.

19. The photosensitive composition according to claim 9, comprising:
a siloxane polymer having a carboxy group and a polymerizable group;
a compound β having a structure that allows an amount of the carboxy group included in the siloxane polymer to reduce upon exposure; and
a filler,
wherein the siloxane polymer has a repeating unit represented by Formula (a1),
the compound β is a nitrogen-containing aromatic compound,
an average particle size of the filler is 300 nm or less, and
a content of the filler is 50 mass % or more with respect to a total solid content of the photosensitive composition, 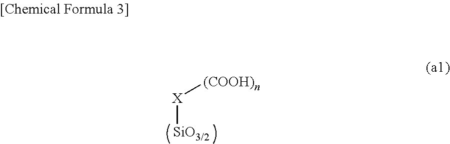
where X represents an (n+1) valent linking group, and n represents an integer of 1 or more.

20. The photosensitive composition according to claim 1, comprising:
a siloxane polymer having a carboxy group; and
a compound β having a structure that allows decarboxylation reaction of the carboxy group included in the siloxane polymer to occur upon exposure to thereby reduce an amount of the carboxy group included in the siloxane polymer,
wherein the siloxane polymer has a repeating unit represented by Formula (a1), and
the compound β includes acridine, 9-alkylacridine, quinoline that may have a substituent, or isoquinoline that may have a substituent, 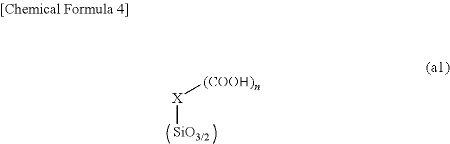
where X represents an (n+1) valent linking group that is one or a combination of two or more selected from the group consisting of a linear or branched divalent aliphatic hydrocarbon group that may have a substituent, —O—, —S—, —SO₂—, >N—, —NR^{S1}—, and —CO—, R^{S1} represents a hydrogen atom or a monovalent organic group, and n represents an integer of 1 or more.

21. The photosensitive composition according to claim 1, comprising:
a siloxane polymer having a carboxy group; and
a compound β having a structure that allows an amount of the carboxy group included in the siloxane polymer to reduce upon exposure,
wherein the siloxane polymer having a carboxy group does not have a structure in which a hydrogen atom of the carboxy group is substituted with an acid labile group, and
the photosensitive composition is substantially free of a polymerizable compound.

22. The photosensitive composition according to claim 1, comprising:
a siloxane polymer having a carboxy group; and
a compound β having a structure that allows an amount of the carboxy group included in the siloxane polymer to reduce upon exposure,
wherein the photosensitive composition is substantially free of an acid generator, and
the photosensitive composition is substantially free of a polymerizable compound.

23. A cured film obtained by curing the photosensitive composition according to claim 1.

24. A cured film obtained by curing the photosensitive composition according to claim 9.
